(19) United States
(12) Patent Application Publication
(10) Pub. No.: US 2025/0311258 A1
(43) Pub. Date: Oct. 2, 2025

(54) SEMICONDUCTOR DEVICE

(71) Applicant: Samsung Electronics Co., Ltd., Suwon-si (KR)

(72) Inventors: Gukil AN, Suwon-si (KR); KyungHwan YANG, Suwon-si (KR); Wookhyun KWON, Suwon-si (KR); Younggwon KIM, Suwon-si (KR); Woncheol JEONG, Suwon-si (KR); Chiwon CHO, Suwon-si (KR)

(73) Assignee: Samsung Electronics Co., Ltd., Suwon-si (KR)

(21) Appl. No.: 19/014,534

(22) Filed: Jan. 9, 2025

(30) Foreign Application Priority Data
Mar. 27, 2024 (KR) 10-2024-0041948

(51) Int. Cl. H10D 10/60; H10D 10/01; H10D 62/13; H10D 62/17

(52) U.S. Cl. CPC H10D 10/60; H10D 10/061; H10D 62/134; H10D 62/137; H10D 62/184

(57) ABSTRACT

A semiconductor device may include a well region disposed in a substrate, an impurity injection region disposed in the well region, an active fin on the well region, a lower insulating layer covering the impurity injection region and the active fin, and a connection pattern provided to penetrate the active fin and connected to the well region. The substrate and the impurity injection region may have a first conductivity type, and the well region may have a second conductivity type different from the first conductivity type. An uppermost portion of the impurity injection region may be in direct contact with the lower insulating layer.

### CROSS-REFERENCE TO RELATED APPLICATIONS

This U.S. non-provisional patent application claims priority under 35 U.S.C. § 119 to Korean Patent Application No. 10-2024-0041948, filed on Mar. 27, 2024, in the Korean Intellectual Property Office, the entire contents of which are hereby incorporated by reference.

### BACKGROUND OF THE INVENTION

The present disclosure relates to a semiconductor device, and in particular, to a semiconductor device including a vertical bipolar junction transistor.

A semiconductor device includes an integrated circuit including metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Accordingly, a variety of studies are being conducted to overcome technical limitations associated with the scale-down of the semiconductor device and to provide high performance semiconductor device. As an example, a multi-bridge channel field effect transistor using a three-dimensional channel may be used to increase an integration density of the semiconductor device, and furthermore, a bipolar junction transistor, which has a structure compatible with the multi-bridge channel field effect transistor, is being proposed.

### SUMMARY

An embodiment of the inventive concept provides a semiconductor device including a vertical bipolar junction transistor with improved electrical characteristics.

An embodiment of the inventive concept provides a semiconductor device, which includes a vertical bipolar junction transistor having a compatible structure with a multi-bridge channel field effect transistor.

According to an embodiment of the inventive concept, a semiconductor device may include a well region disposed in a substrate, an impurity injection region disposed in the well region, an active fin on the well region, a lower insulating layer covering the impurity injection region and the active fin, and a connection pattern provided to penetrate the active fin and connected to the well region. The substrate and the impurity injection region may have a first conductivity type, and the well region may have a second conductivity type different from the first conductivity type. An uppermost portion of the impurity injection region may be in direct contact with the lower insulating layer.

According to an embodiment of the inventive concept, a semiconductor device may include a well region disposed in a substrate, an impurity injection region disposed in the well region, a first active fin disposed on the well region, the first active fin including first semiconductor patterns, which are spaced apart from each other in a vertical direction perpendicular to a top surface of the substrate, a second active fin disposed on the substrate, the second active fin including second semiconductor patterns, which are spaced apart from each other in the vertical direction, a first connection pattern provided to penetrate the first active fin and connected to the well region, a second connection pattern provided to penetrate the second active fin and connected to the substrate, and a lower insulating layer covering the first and second active fins. The substrate and the impurity injection region may have a first conductivity type, and the well region may have a second conductivity type different from the first conductivity type. An uppermost portion of the impurity injection region may be in direct contact with the lower insulating layer.

According to an embodiment of the inventive concept, a semiconductor device may include device isolation patterns disposed in a substrate, a first active pattern, a second active pattern, and a third active pattern, which are spaced apart from each other with the device isolation patterns interposed therebetween, a first active fin on the second active pattern, and a lower insulating layer covering the first active fin. The first active pattern may include an impurity injection region of a first conductivity type, the second active pattern may include a well region of a second conductivity type different from the first conductivity type, and the third active pattern may have the first conductivity type. The lower insulating layer may be in direct contact with a top surface of the first active pattern.

According to an embodiment of the inventive concept, a semiconductor device may include a well region disposed in a substrate, an impurity injection region disposed in the well region, a plurality of active fins comprising a first active fin disposed on the well region, the first active fin comprising first semiconductor patterns, which are spaced apart from each other in a vertical direction perpendicular to a top surface of the substrate, and a second active fin disposed on the substrate, the second active fin comprising second semiconductor patterns, which are spaced apart from each other in the vertical direction, a first connection pattern provided to penetrate the first active fin and connected to the well region, a second connection pattern provided to penetrate the second active fin and connected to the substrate, a penetration contact plug in direct contact with the impurity injection region. The substrate and the impurity injection region may have a first conductivity type. The well region may have a second conductivity type different from the first conductivity type. The plurality of active fins may be spaced apart from the impurity injection region and the penetration contact plug.

### BRIEF DESCRIPTION OF THE DRAWINGS

FIG. 1 is a plan view illustrating a semiconductor device according to an embodiment of the inventive concept.

FIGS. 2A, 2B, and 2C are sectional views taken along lines A-A′, B-B′, and C-C′ of FIG. 1, respectively.

FIGS. 3A, 4A, 5A, 6A, 7A, and 8A which are sectional views taken along the line A-A′ of FIG. 1, FIGS. 3B, 4B, 5B, 6B, 7B, and 8B which are sectional views taken along the line B-B′ of FIG. 1, and FIGS. 3C, 4C, 5C, 6C, 7C, and 8C which are sectional views taken along the line C-C′ of FIG. 1 illustrate a method of fabricating a semiconductor device according to an embodiment of the inventive concept.

FIGS. 9A and 9B are sectional views, which are respectively taken along the lines A-A′ and C-C′ of FIG. 1 to illustrate a semiconductor device according to an embodiment of the inventive concept.

FIGS. 10A and 10B are sectional views, which are respectively taken along the lines A-A′ and C-C′ of FIG. 1 to illustrate a method of fabricating a semiconductor device according to an embodiment of the inventive concept.

FIG. 11 is a sectional view, which is taken along the line A-A′ of FIG. 1 to illustrate a semiconductor device according to an embodiment of the inventive concept.

FIGS. 12 to 14 are sectional views, which are taken along the line A-A′ of FIG. 1 to illustrate a method of fabricating a semiconductor device according to an embodiment of the inventive concept.

FIGS. 15 and 16 are sectional views, which are taken along the line A-A′ of FIG. 1 to illustrate a semiconductor device according to an embodiment of the inventive concept.

### DETAILED DESCRIPTION

Example embodiments of the inventive concepts will now be described more fully with reference to the accompanying drawings, in which example embodiments are shown.

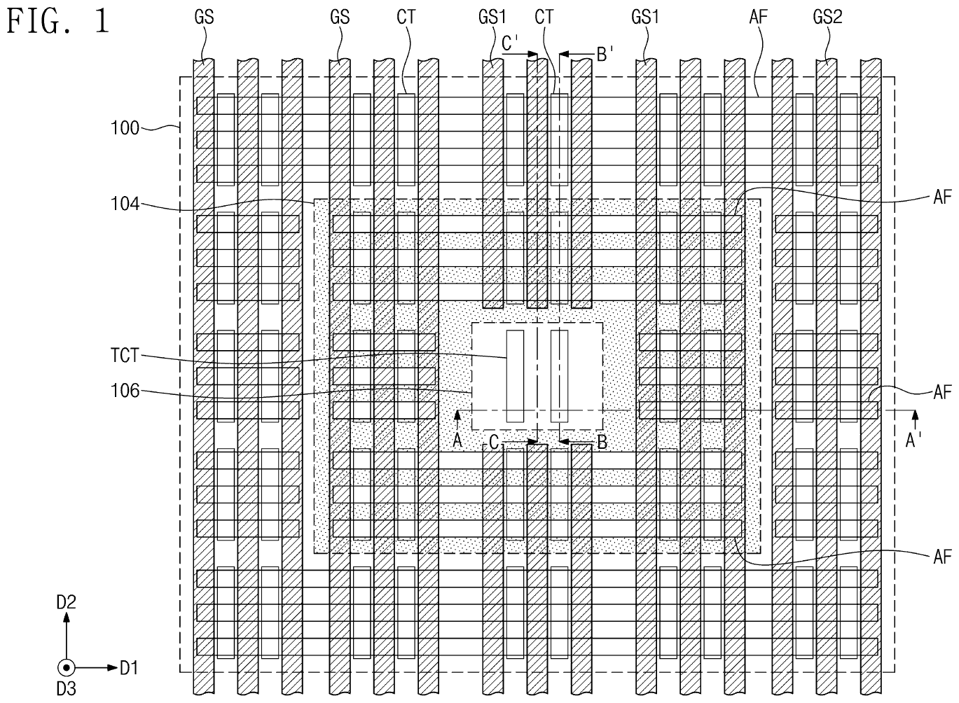

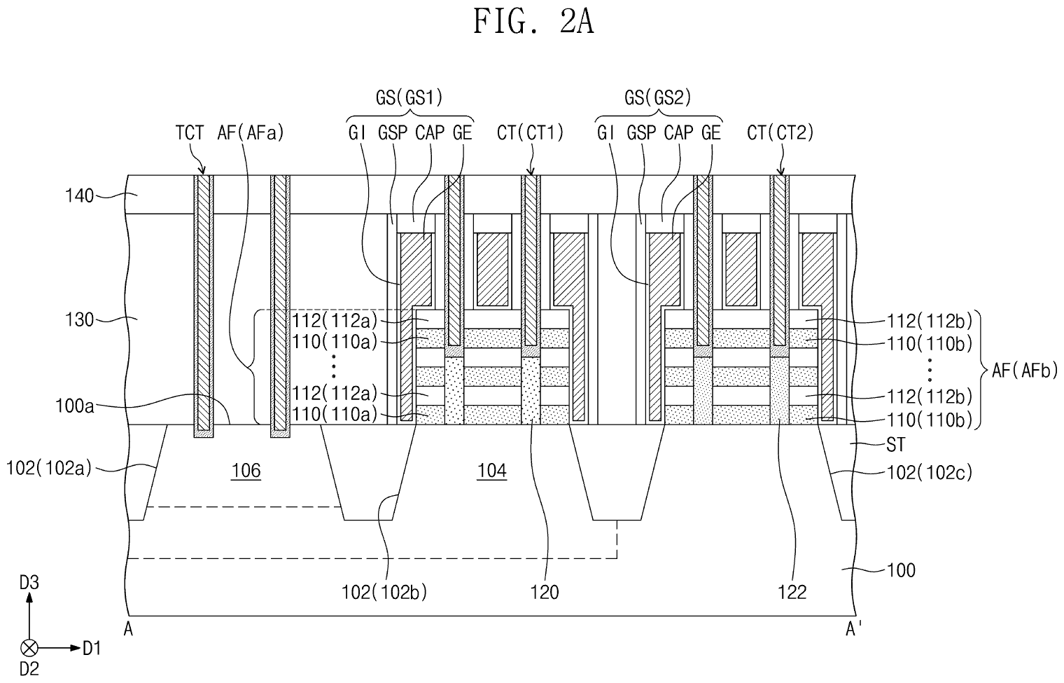

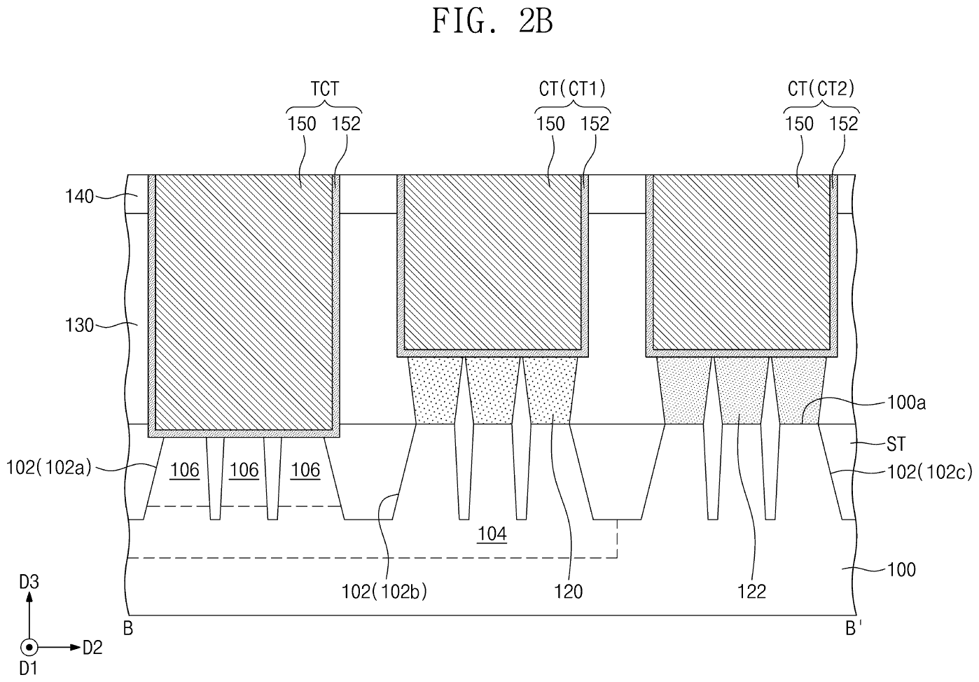

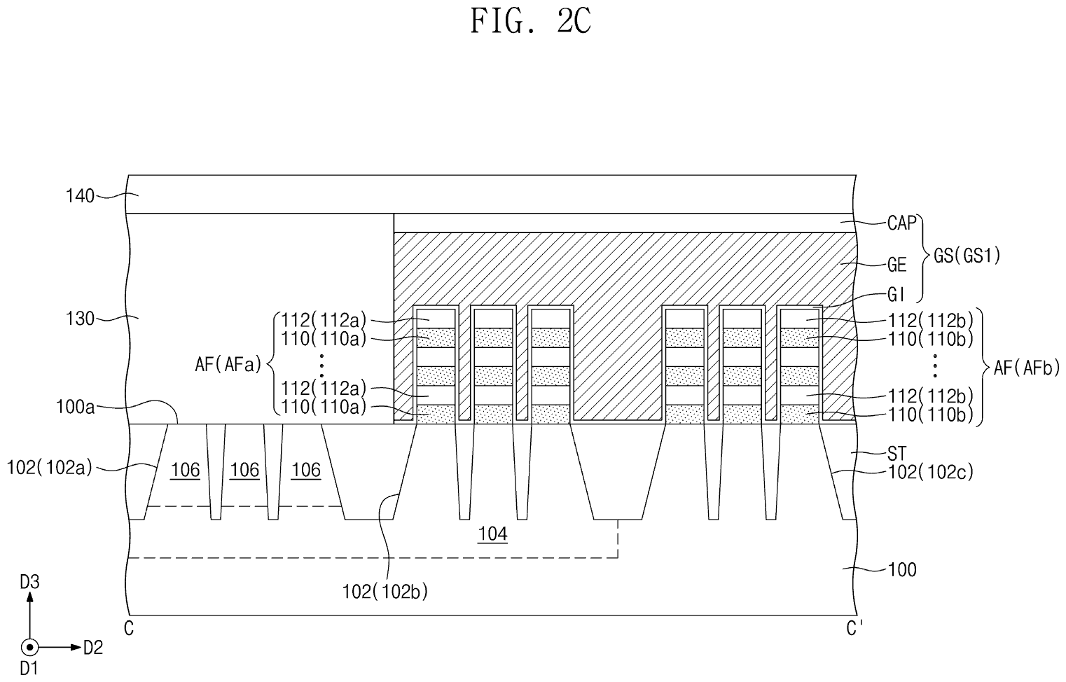

FIG. 1 is a plan view illustrating a semiconductor device according to an embodiment of the inventive concept. FIGS. 2A, 2B, and 2C are sectional views taken along lines A-A′, B-B′, and C-C′ of FIG. 1, respectively.

Referring to FIGS. 1, 2A, 2B, and 2C, a well region 104 may be disposed in a substrate 100. The substrate 100 may be a semiconductor substrate (e.g., a silicon wafer or a silicon-on-insulator (SOI) wafer). The substrate 100 may have a first conductivity type, and the well region 104 may have a second conductivity type different from the first conductivity type. As an example, the first conductivity type may be a p type, and the second conductivity type may be an n type. An impurity injection region 106 may be disposed in the well region 104. The impurity injection region 106 may have the same conductivity type as the substrate 100. In an embodiment, the impurity injection region 106 may contain impurities of the first conductivity type.

Device isolation patterns ST may be disposed in the substrate 100. The substrate 100 may include active patterns 102, which are defined by the device isolation patterns ST. The active patterns 102 may protrude from a lower portion of the substrate 100 in a vertical direction (i.e., a third direction D3) perpendicular to a top surface 100a of the substrate 100. Each of the device isolation patterns ST may be interposed between corresponding ones of the active patterns 102. The device isolation patterns ST may be formed of or include at least one of oxide, nitride, and/or oxynitride materials.

The active patterns 102 may include a first active pattern 102a, a second active pattern 102b, and a third active pattern 102c, which are spaced apart from each other in a first direction D1 parallel to the top surface 100a of the substrate 100. The first active pattern 102a may include the impurity injection region 106, and the second active pattern 102b may include the well region 104. The third active pattern 102c may be a portion of the substrate 100. One of the device isolation patterns ST may be interposed between the first active pattern 102a and the second active pattern 102b. The well region 104 may be extended to a lower portion of the first active pattern 102a along a bottom surface of one of the device isolation patterns ST. Thus, a boundary between the impurity injection region 106 and the well region 104 may be disposed in the lower portion of the first active pattern 102a. The impurity injection region 106 and the well region 104 may form a PN junction in the lower portion of the first active pattern 102a. Another one of the device isolation patterns ST may be interposed between the second active pattern 102b and the third active pattern 102c and may be placed on a boundary between the well region 104 and the substrate 100. The well region 104 and the substrate 100 may form a PN junction, below the device isolation patterns ST.

Active fins AF may be disposed on the second and third active patterns 102b and 102c, respectively. In an embodiment, each of the active fins AF may include sacrificial patterns 110 and semiconductor patterns 112, which are alternately stacked on each of the second and third active patterns 102b and 102c in the third direction D3. The sacrificial patterns 110 may include a material different from the semiconductor patterns 112. In an embodiment, the semiconductor patterns 112 may include silicon (Si), and the sacrificial patterns 110 may include silicon germanium (SiGe).

The active fins AF may include a first active fin AFa on the second active pattern 102b and a second active fin AFb on the third active pattern 102c. The semiconductor and sacrificial patterns 112 and 110 of the first active fin AFa may be referred to as first semiconductor patterns 112a and first sacrificial patterns 110a, and the semiconductor and sacrificial patterns 112 and 110 of the second active fin AFb may be referred to as second semiconductor patterns 112b and second sacrificial patterns 110b. The first and second semiconductor patterns 112a and 112b may include the same material (i.e., silicon), and the first and second sacrificial patterns 110a and 110b may include the same material (i.e., silicon germanium).

A first connection pattern 120 may be provided to penetrate the first active fin AFa and may be connected to the well region 104. In an embodiment, the first connection pattern 120 may be provided to penetrate the first semiconductor patterns 112a and the first sacrificial patterns 110a and may be connected to the well region 104. The first connection pattern 120 may be an epitaxial pattern, which is formed using the first semiconductor patterns 112a, the first sacrificial patterns 110a, and the second active pattern 102b as a seed layer. The first connection pattern 120 may be formed of or include at least one of silicon germanium (SiGe), silicon (Si), or silicon carbide (SiC). The first connection pattern 120 may further contain impurities of the second conductivity type.

A second connection pattern 122 may be provided to penetrate the second active fin AFb and may be connected to the substrate 100. In an embodiment, the second connection pattern 122 may be provided to penetrate the second semiconductor patterns 112b and the second sacrificial patterns 110b and may be connected to the substrate 100. The second connection pattern 122 may be an epitaxial pattern, which is formed using the second semiconductor patterns 112b, the second sacrificial patterns 110b, and the third active pattern 102c as a seed layer. The second connection pattern 122 may be formed of or include at least one of silicon germanium (SiGe), silicon (Si), or silicon carbide (SiC). The second connection pattern 122 may further contain impurities of the first conductivity type.

Gate structures GS may be disposed on the substrate 100 to cross the active fins AF. The gate structures GS may be extended in a second direction D2 that is parallel to the top surface 100a of the substrate 100 and is not parallel to the first direction D1. The gate structures GS may include first gate structures GS1 and second gate structures GS2. The first gate structures GS1 may be provided to cross the active fins AF (i.e., the first active fins AFa) on the well region 104 and may be extended in the second direction D2 to cross the active fins AF (i.e., the second active fins AFb) on a portion of the substrate 100, in which the well region 104 is not formed. The second gate structure GS2 may be provided to cross the active fins AF on a portion of the substrate 100, in which the well region 104 is not formed. The gate structures GS may be spaced apart from each other in the first direction D1.

Each of the gate structures GS may include a gate electrode GE, which is extended in the second direction D2 to cross corresponding active fins AF of the active fins AF, a gate insulating pattern GI, which is provided between the gate electrode GE and the corresponding active fin AF, gate spacers GSP, which are provided on side surfaces of the gate electrode GE, and a gate capping pattern CAP, which is provided on a top surface of the gate electrode GE. The gate insulating pattern GI may be extended into a space between the gate electrode GE and the gate spacers GSP, and the topmost surface of the gate insulating pattern GI may be substantially coplanar with the top surface of the gate electrode GE. The gate spacers GSP may be extended to face side surfaces of the gate capping pattern CAP. The gate electrode GE of each of the first gate structures GS1 may cover side surfaces of the corresponding active fins AF. The gate insulating pattern GI of each of the first gate structures GS1 may be interposed between the gate electrode GE and the corresponding active fins AF. The gate electrode GE of each of the second gate structures GS2 may be provided to cross the corresponding active fins AF and cover side surfaces of the corresponding active fins AF. The gate insulating pattern GI of each of the second gate structures GS2 may be interposed between the gate electrode GE and the corresponding active fins AF.

The gate electrode GE may be formed of or include a doped semiconductor material, a conductive metal nitride material, and/or a metallic material. The gate insulating pattern GI may be formed of or include at least one of silicon oxide, silicon nitride, silicon oxynitride, or high-k dielectric materials. The high-k dielectric materials may include materials (e.g., hafnium oxide, aluminum oxide, or tantalum oxide) whose dielectric constants are higher than silicon oxide. Each of the gate spacers GSP and the gate capping pattern CAP may include at least one of a silicon oxide layer, a silicon nitride layer, and a silicon oxynitride layer.

A lower insulating layer 130 may be disposed on the substrate 100 to cover the gate structures GS, the active fins AF, and the first and second connection patterns 120 and 122. The lower insulating layer 130 may be extended in two different horizontal directions (i.e., the first and second directions D1 and D2), which are parallel to the top surface 100a of the substrate 100, to cover the impurity injection region 106. The lower insulating layer 130 may be in direct contact with the uppermost portion of the impurity injection region 106. In other words, the lower insulating layer 130 may be in direct contact with a top surface of the impurity injection region 106. The lower insulating layer 130 may include at least one of a silicon oxide layer, a silicon nitride layer, a silicon oxynitride layer, or low-k dielectric layers. A top surface of the gate capping pattern CAP of each of the gate structures GS may be substantially coplanar with a top surface of the lower insulating layer 130. The gate spacers GSP of each of the gate structures GS may be interposed between the gate capping pattern CAP and the lower insulating layer 130.

An upper insulating layer 140 may be disposed on the lower insulating layer 130. The upper insulating layer 140 may include an oxide layer, a nitride layer, and/or an oxynitride layer. The upper insulating layer 140 may cover the top surface of the gate capping pattern CAP of each of the gate structures GS.

Contact plugs CT may be disposed in the lower insulating layer 130 and may be extended into the upper insulating layer 140. Each of the contact plugs CT may include a conductive pattern 150, which is provided to penetrate the upper insulating layer 140 and is extended into the lower insulating layer 130, and a barrier pattern 152, which is provided to cover side and bottom surfaces of the conductive pattern 150. In an embodiment, the conductive pattern 150 may be formed of or include at least one of metallic materials, and the barrier pattern 152 may be formed of or include at least one of conductive metal nitride materials.

Penetration contact plugs TCT may be disposed in the lower insulating layer 130 and may be extended into the upper insulating layer 140. The penetration contact plug TCT may be connected to the impurity injection region 106. The penetration contact plugs TCT may be provided to penetrate the upper and lower insulating layers 140 and 130 and to be in direct contact with the impurity injection region 106. The penetration contact plugs TCT may be spaced apart from each other in the first direction D1. A bottom surface of the penetration contact plug TCT may be located at a level lower than the top surface 100a of the substrate 100. Each of the penetration contact plugs TCT may include the conductive pattern 150 and the barrier pattern 152, which is provided to cover side and bottom surfaces of the conductive pattern 150. The conductive pattern 150 and the barrier pattern 152 may be formed of or include the same materials as the conductive pattern 150 and the barrier pattern 152 of the contact plugs CT.

The contact plugs CT may include a first contact plug CT1, which is connected to the first connection pattern 120, and a second contact plug CT2, which is connected to the second connection pattern 122.

The first contact plug CT1 may be interposed between the first gate structures GS1, may be provided to penetrate the first active fin AFa, and may be connected to the first connection pattern 120. The first contact plug CT1 may have side surfaces that are in contact with the gate spacers GSP of the first gate structures GS1. In an embodiment, the second active patterns 102b may be arranged to be spaced apart from each other in the second direction D2, and the first active fins AFa may be disposed on the second active patterns 102b, respectively. In this case, the first connection patterns 120 may penetrate the second active fins AFb and may be connected to the well region 104. The first contact plug CT1 may be extended in the second direction D2 and may be connected to the first connection patterns 120.

The second contact plug CT2 may be interposed between the second gate structures GS2, may be provided to penetrate the second active fin AFb, and may be connected to the second connection pattern 122. The second contact plug CT2 may be in contact with the gate spacers GSP of the second gate structures GS2. In an embodiment, the third active patterns 102c may be arranged to be spaced apart from each other in the second direction D2, and the second active fins AFb may be disposed on the third active patterns 102c, respectively. In this case, the second connection patterns 122 may penetrate the second active fins AFb and may be connected to the substrate 100. The second contact plug CT2 may be extended in the second direction D2 and may be connected to the second connection patterns 122.

The impurity injection region 106 and the penetration contact plug TCT may constitute an emitter of a vertical bipolar junction transistor. The well region 104, the second active pattern 102b, the first active fin AFa, the first connection pattern 120, the first gate structures GS1, and the first contact plug CT1 may constitute a base of the vertical bipolar junction transistor. The substrate 100, the third active pattern 102c, the second active fin AFb, the second connection pattern 122, the second gate structures GS2, and the second contact plug CT2 may constitute a collector of the vertical bipolar junction transistor. The first and second gate structures GS1 and GS2 may be dummy gate structures that are in an electrically floated state.

According to an embodiment of the inventive concept, the impurity injection region 106 may contain impurities of the first conductivity type, and the impurity injection region 106 and the well region 104 may form a PN junction in a lower portion of the first active pattern 102a. Since an ion implantation process is performed after the removing of the active fins from the impurity injection region 106, it may be possible to form the PN junction in the lower portion of the first active pattern 102a. Since a density of state is lower in the lower portion of the first active pattern 102a than in the upper portion, it may be possible to improve the uniformity of voltage values more effectively. In addition, since a PNP junction of the vertical bipolar junction transistor is formed adjacent to a lower portion of the device isolation pattern ST, it may be possible to prevent or suppress a leakage current issue.

Furthermore, the penetration contact plug TCT may be in direct contact with or connected to the impurity injection region 106, and this may make it possible to reduce an electric resistance between the impurity injection region 106 and the penetration contact plug TCT. Accordingly, the electric characteristics of the semiconductor device may be improved.

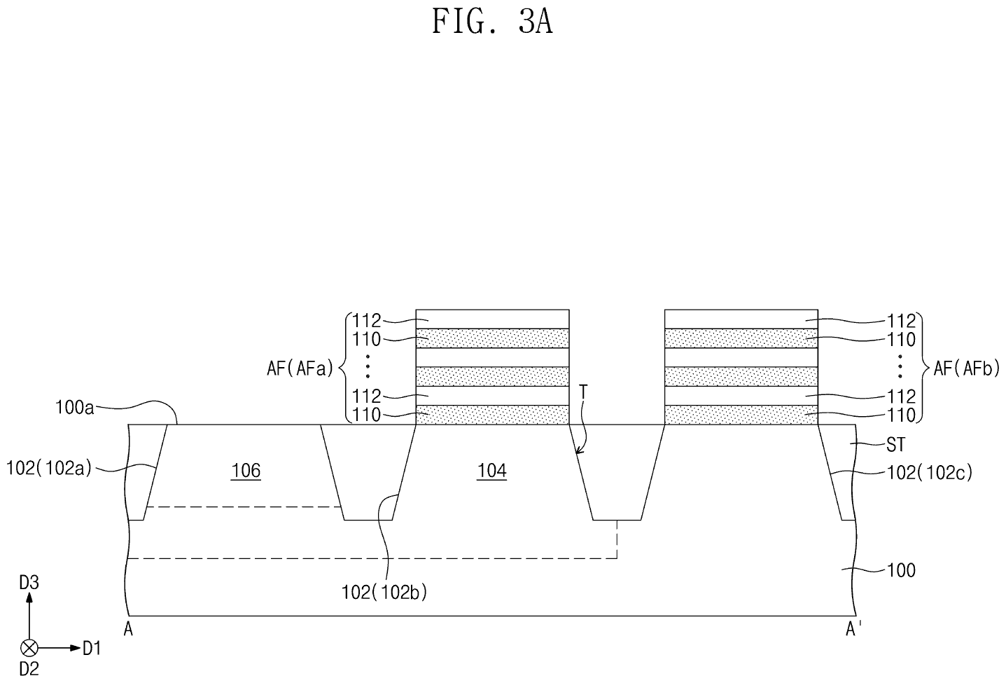

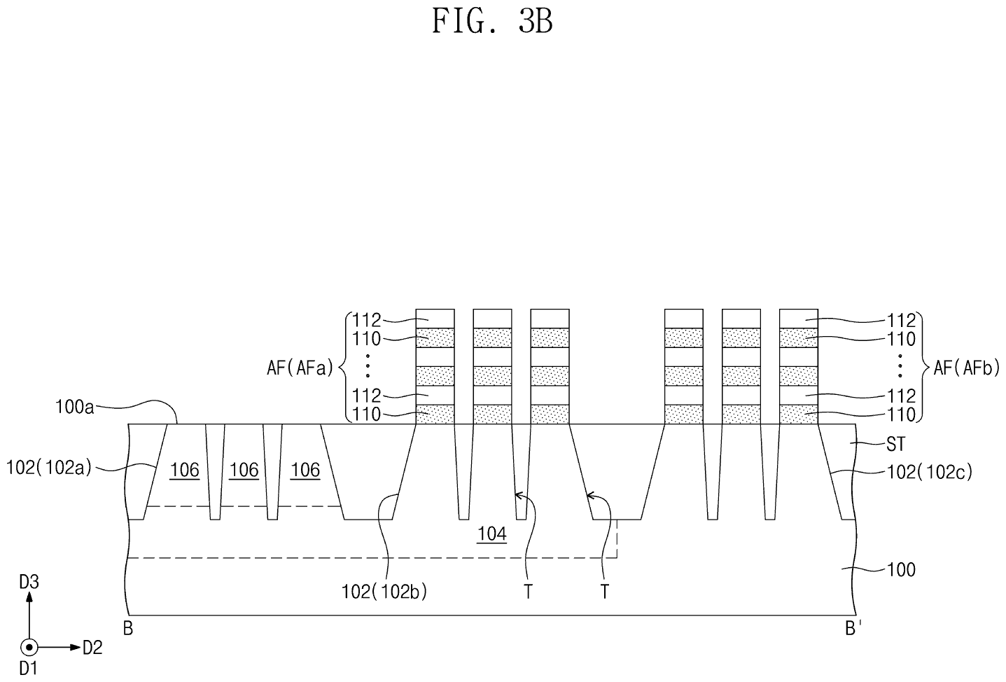

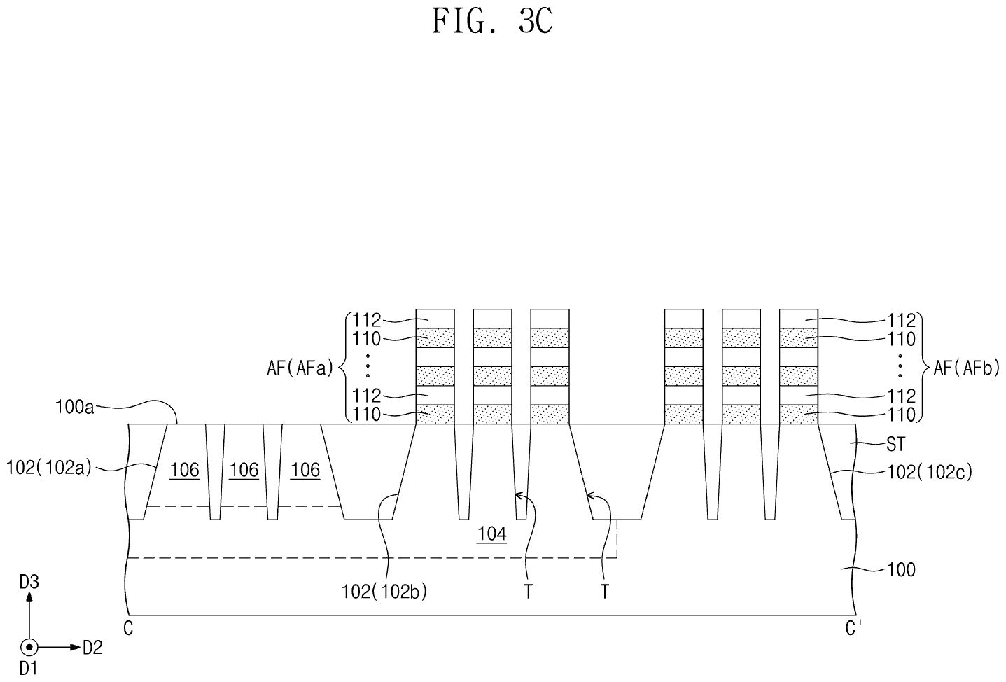

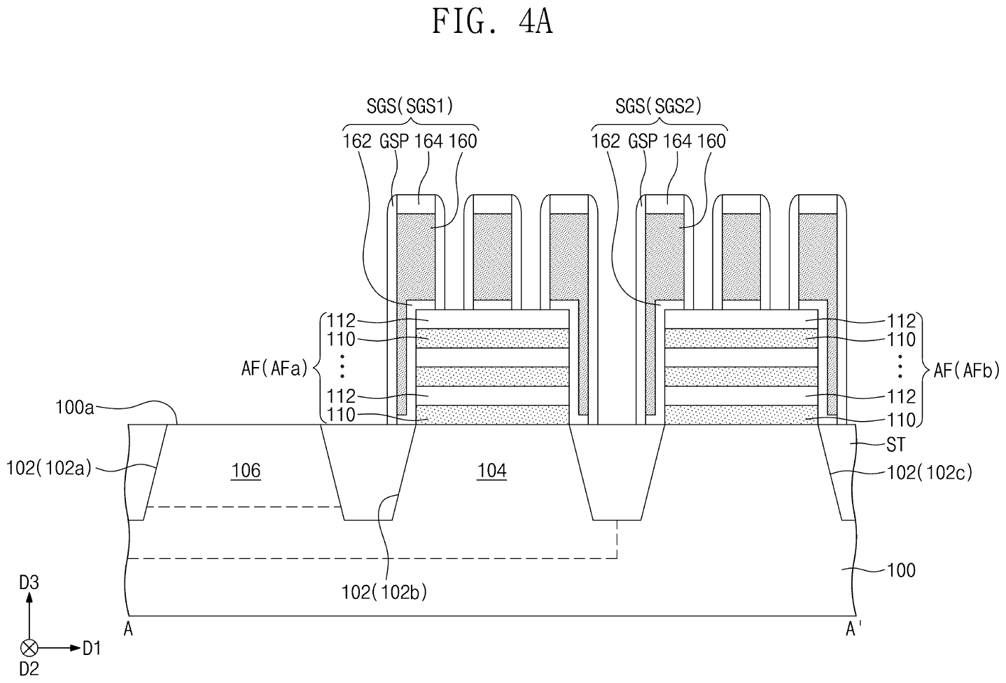

FIGS. 3A, 4A, 5A, 6A, 7A, and 8A which are sectional views taken along the line A-A′ of FIG. 1, FIGS. 3B, 4B, 5B, 6B, 7B, and 8B which are sectional views taken along the line B-B′ of FIG. 1, and FIGS. 3C, 4C, 5C, 6C, 7C, and 8C which are sectional views taken along the line C-C′ of FIG. 1 illustrate a method of fabricating a semiconductor device according to an embodiment of the inventive concept. For concise description, an element previously described with reference to FIGS. 1, 2A, 2B, and 2C may be identified by the same reference number without repeating an overlapping description thereof.

Referring to FIGS. 1, 3A, 3B, and 3C, the well region 104 may be formed in the substrate 100. The substrate 100 may have a first conductivity type, and the well region 104 may have a second conductivity type different from the first conductivity type. The well region 104 may be formed by injecting impurities of the second conductivity type into the substrate 100.

The active patterns 102 may be formed in the substrate 100. The active fins AF may be formed on the second active pattern 102b and the third active pattern 102c, respectively. In an embodiment, the formation of the active fins AF may include alternately and repeatedly stacking sacrificial layers and semiconductor layers on the substrate 100 and sequentially patterning the sacrificial and semiconductor layers. The sacrificial and semiconductor layers, which are formed on the first active pattern 102a, may be etched and removed by the patterning process. That is, the active fins may not be formed on the first active pattern 102a. As a result of the patterning of the sacrificial and semiconductor layers, the sacrificial and semiconductor patterns 110 and 112 may be formed. Each of the active fins AF may include the sacrificial and semiconductor patterns 110 and 112, which are alternatingly stacked on the substrate 100.

The formation of the active patterns 102 may include patterning an upper portion of the substrate 100 to form trenches T, which define the active patterns 102, in the substrate 100. The active patterns 102 may protrude from a lower portion of the substrate 100 in the third direction D3, which is perpendicular to the top surface 100a of the substrate 100. The active patterns 102 may include the first active pattern 102a, the second active pattern 102b, and the third active pattern 102c, which are spaced apart from each other in the first direction D1 parallel to the top surface 100a of the substrate 100. The first active pattern 102a and the second active pattern 102b may be formed on the well region 104, and the third active pattern 102c may be formed on a portion of the substrate 100, in which the well region 104 is not formed. The active fins AF may include the first active fin AFa on the second active pattern 102b and the second active fin AFb on the third active pattern 102c.

The device isolation patterns ST may be formed in the substrate 100. The formation of the device isolation patterns ST may include forming an insulating layer to fill the trenches T and recessing the insulating layer to expose the active fins AF. The recessing of the insulating layer may be performed to expose a top surface of each of the active fins AF, and in an embodiment, side surfaces (i.e., the side surfaces of the sacrificial and semiconductor patterns 110 and 112) of each of the active fins AF may be exposed to the outside by the recessing of the insulating layer.

The impurity injection region 106 may be formed in the first active pattern 102a. The formation of the impurity injection region 106 may include injecting impurities of the second conductivity type in the first active pattern 102a. Since the injection of the impurities is performed on the first active pattern 102a, on which the active fin is not formed, the impurities may be injected to a relatively large depth. Thus, it may be possible to easily form a boundary between the impurity injection region 106 and the well region 104 in a lower portion of the first active pattern 102a. Accordingly, the impurity injection region 106 and the well region 104 may form a PN junction in the lower portion of the first active pattern 102a. The well region 104 and the substrate 100 may form a PN junction, below the device isolation patterns ST.

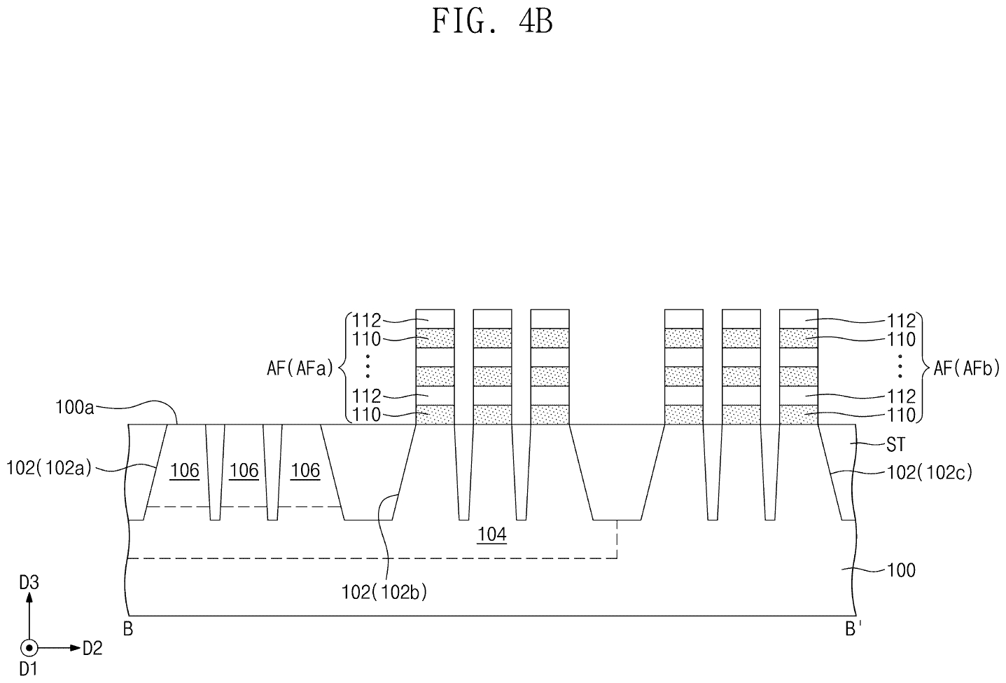

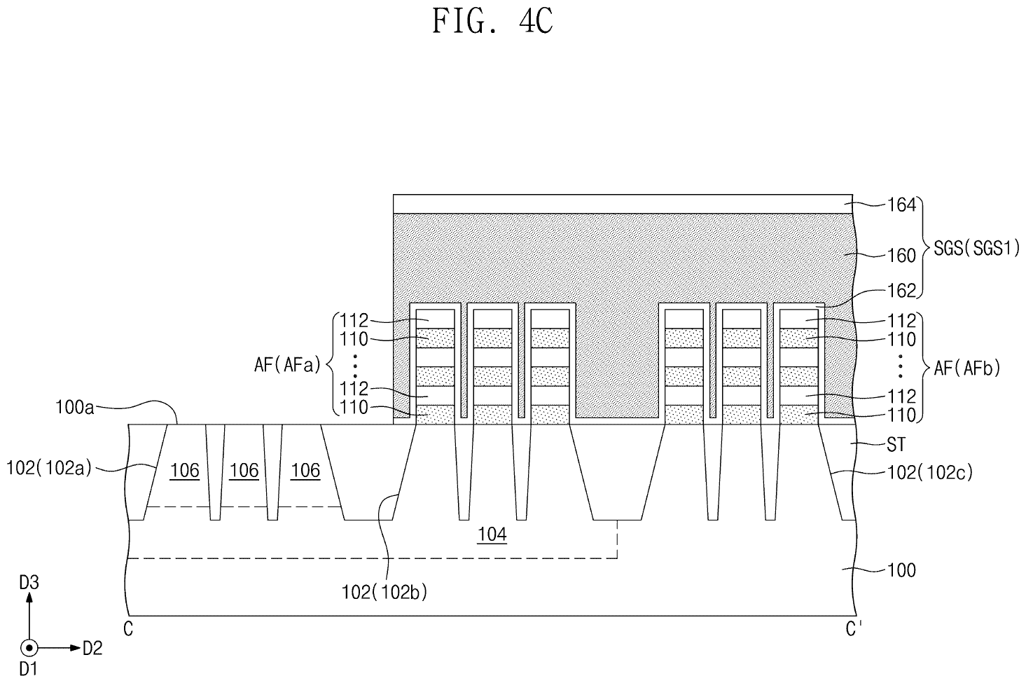

Referring to FIGS. 1, 4A, 4B, and 4C, sacrificial gate structures SGS may be formed on the substrate 100 to cross the active fins AF. The sacrificial gate structures SGS may be extended in the second direction D2, which is parallel to the top surface 100a of the substrate 100 and is not parallel to the first direction D1. The sacrificial gate structures SGS may include first sacrificial gate structures SGS1 and second sacrificial gate structures SGS2. The first sacrificial gate structures SGS1 may be provided to cross the active fins AF (i.e., the first active fins AFa) on the well region 104 and may be extended in the second direction D2 to cross the active fins AF (i.e., the second active fins AFb) on a portion of the substrate 100, in which the well region 104 is not formed. The second sacrificial gate structure SGS2 may be provided to cross the active fins AF on a portion of the substrate 100, in which the well region 104 is not formed. The first and second sacrificial gate structures SGS1 and SGS2 may be spaced apart from each other in the first direction D1, on the correspond active fin AF.

Each of the sacrificial gate structures SGS may include an etch stop pattern 162, a sacrificial gate pattern 160, and a gate mask pattern 164, which are sequentially stacked on the substrate 100. The sacrificial gate pattern 160 may be a line-shaped pattern that is extended in the second direction D2 to cross corresponding active fins AF of the active fins AF. The sacrificial gate pattern 160 may cover side surfaces of the correspond active fin AF. The etch stop pattern 162 may be interposed between the sacrificial gate pattern 160 and the correspond active fin AF, and the gate mask pattern 164 may be extended along a top surface of the sacrificial gate pattern 160.

The formation of the sacrificial gate pattern 160 and the etch stop pattern 162 may include sequentially forming an etch stop layer (not shown) and a sacrificial gate layer (not shown) on the substrate 100, forming the gate mask pattern 164 on the sacrificial gate layer to define a region for the sacrificial gate pattern 160, and sequentially patterning the sacrificial gate layer and the etch stop layer using the gate mask pattern 164 as an etch mask. The etch stop layer may be formed of or include, for example, silicon oxide. The sacrificial gate layer may include a material having an etch selectivity with respect to the etch stop layer. The sacrificial gate layer may be formed of or include, for example, poly silicon. The sacrificial gate pattern 160 may be formed by patterning the sacrificial gate layer using the gate mask pattern 164 as an etch mask. The patterning of the sacrificial gate layer may include performing an etching process, which is chosen to have an etch selectivity with respect to the etch stop layer. After the formation of the sacrificial gate pattern 160, the etch stop pattern 162 may be locally formed below the sacrificial gate pattern 160 by removing the etch stop layer from both sides of the sacrificial gate pattern 160.

Each of the sacrificial gate structures SGS may further include the gate spacers GSP, which are placed at both sides of the sacrificial gate pattern 160. The formation of the gate spacers GSP may include forming a gate spacer layer (not shown) on the substrate 100 to cover the gate mask pattern 164, the sacrificial gate pattern 160, and the etch stop pattern 162 and anisotropically etching the gate spacer layer. In an embodiment, the gate mask pattern 164 and the gate spacers GSP may be formed of or include silicon nitride.

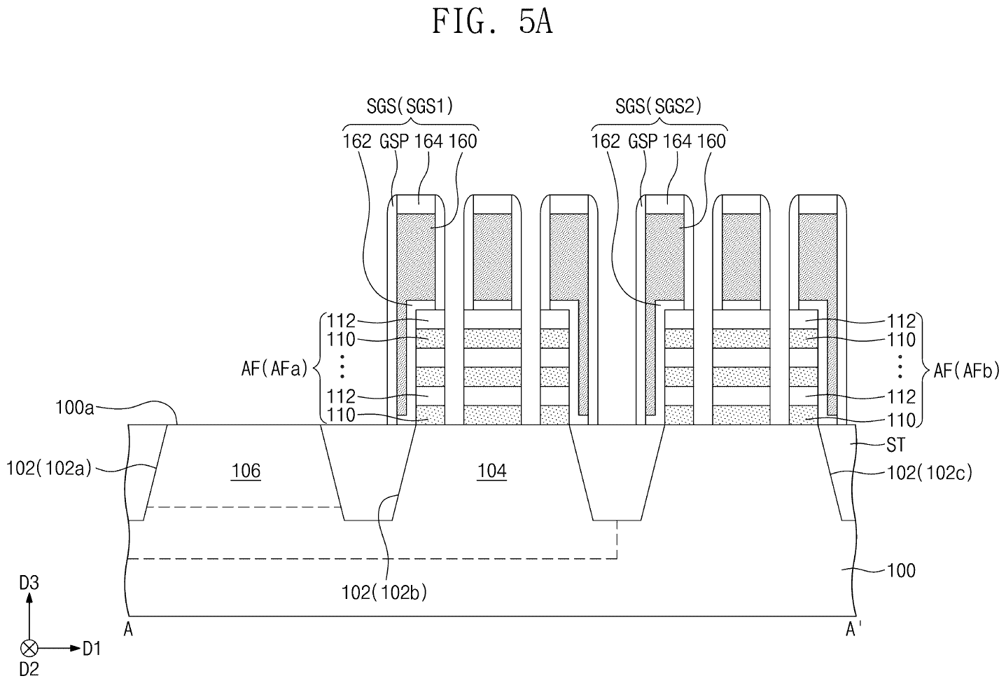

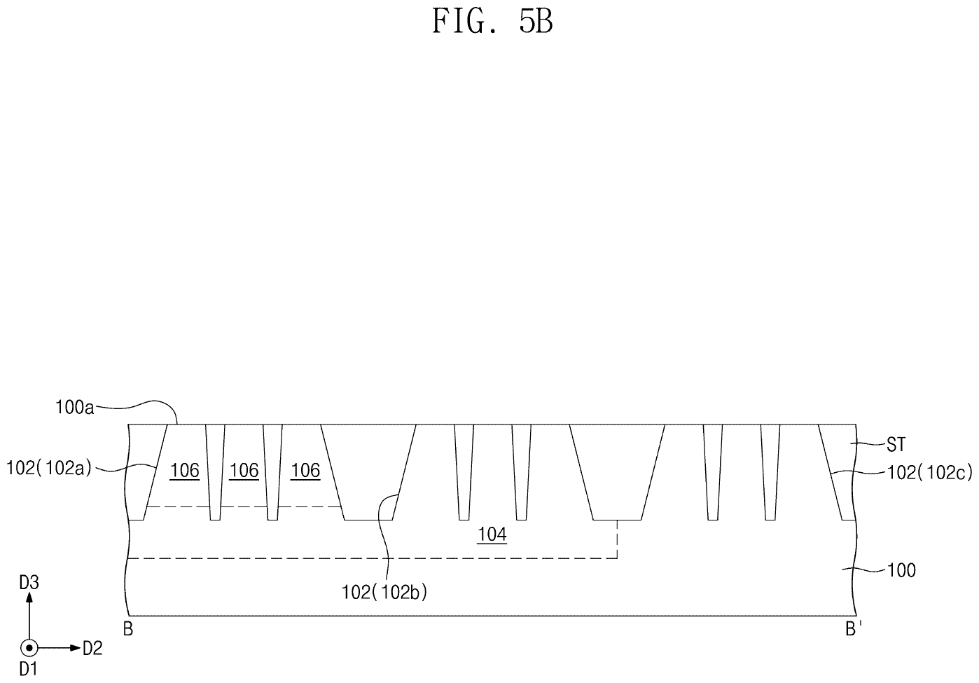

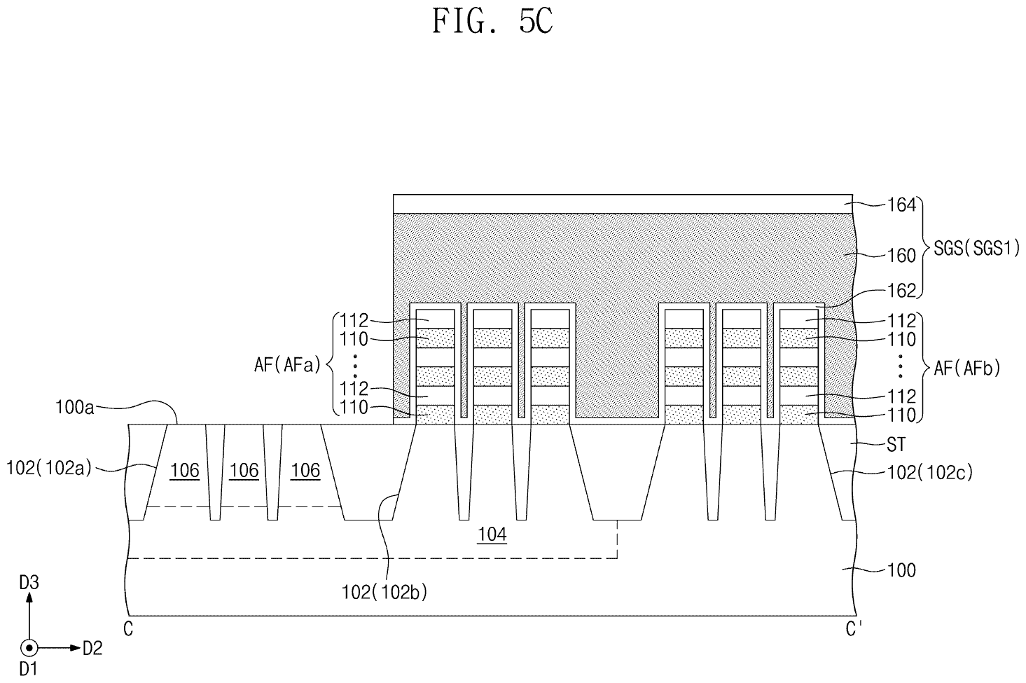

Referring to FIGS. 1, 5A, 5B, and 5C, a portion of the correspond active fin AF between the first sacrificial gate structures SGS1 may be removed. In an embodiment, a portion of the first active fin AFa may be removed, and thus, a top surface of the second active pattern 102b may be exposed between the first sacrificial gate structures SGS1. A portion of the correspond active fin AF between the second sacrificial gate structures SGS2 may be removed. In an embodiment, a portion of the second active fin AFb may be removed, and thus, a top surface of the third active pattern 102c may be exposed between the second sacrificial gate structures SGS2.

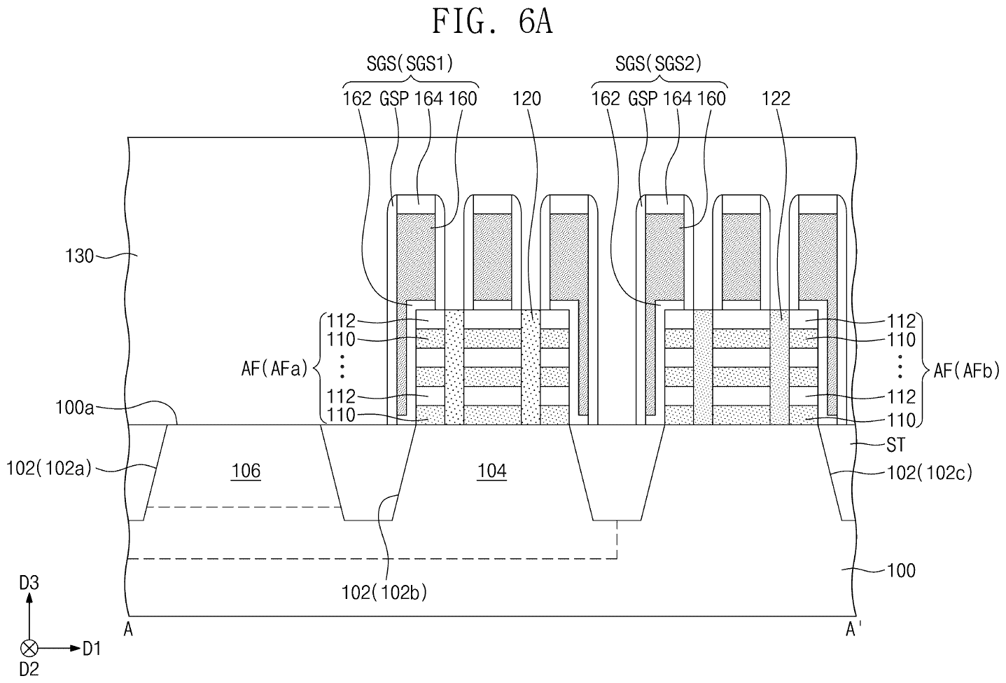

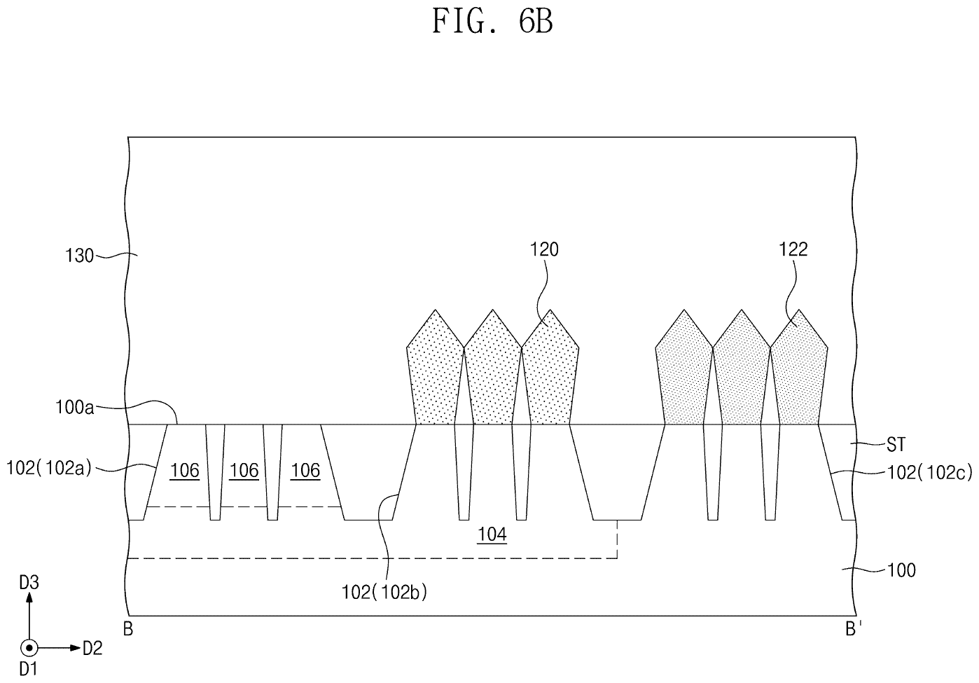

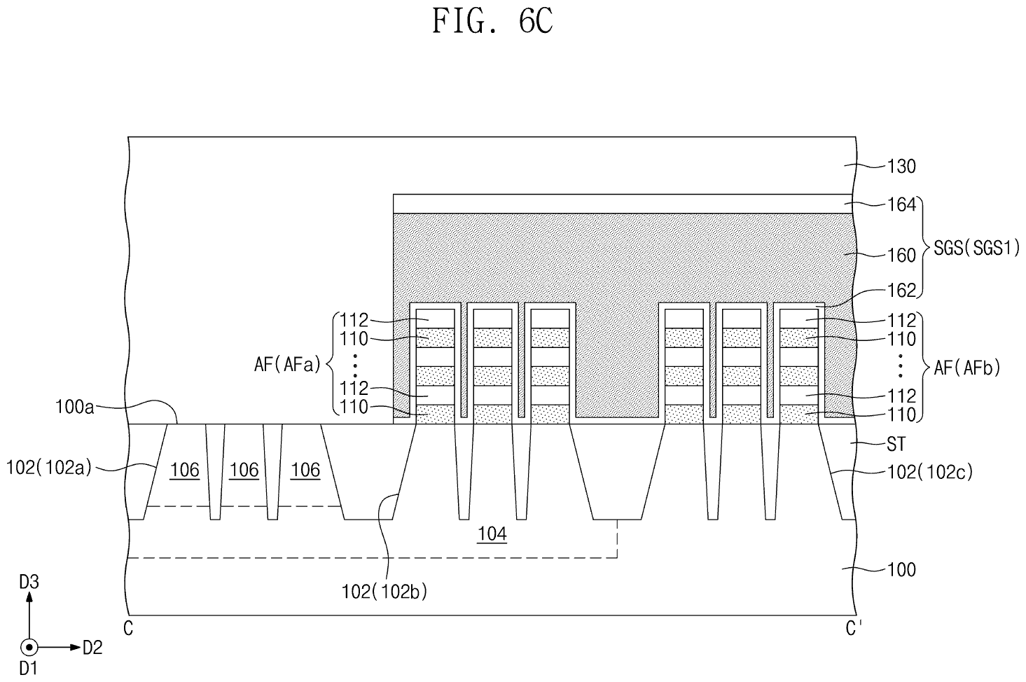

Referring to FIGS. 1, 6A, 6B, and 6C, the first connection pattern 120 may be formed on the second active pattern 102b between the first sacrificial gate structures SGS1. The first connection pattern 120 may be formed by performing a selective epitaxial growth process, in which the semiconductor and sacrificial patterns 112 and 110 of the first active fin AFa and the exposed top surface of the second active pattern 102b are used as a seed layer. The first connection pattern 120 may be in contact with the side surfaces of the semiconductor and sacrificial patterns 112 and 110 of the first active fin AFa and may be connected to the well region 104. The formation of the first connection pattern 120 may further include doping the first connection pattern 120 with impurities of the second conductivity type, during or after the selective epitaxial growth process.

The second connection pattern 122 may be formed on the third active pattern 102c between the second sacrificial gate structures SGS2. The second connection pattern 122 may be formed by performing a selective epitaxial growth process, in which the semiconductor and sacrificial patterns 112 and 110 of the second active fin AFb and the exposed top surface of the third active pattern 102c are used as a seed layer. The second connection pattern 122 may be in contact with the side surfaces of the semiconductor and sacrificial patterns 112 and 110 of the second active fin AFb and may be connected to the substrate 100. The formation of the second connection pattern 122 may further include doping the second connection pattern 122 with impurities of the first conductivity type, during or after the selective epitaxial growth process.

The lower insulating layer 130 may be formed on the substrate 100 to cover the active fins AF, the first and second connection patterns 120 and 122, and the sacrificial gate structures SGS.

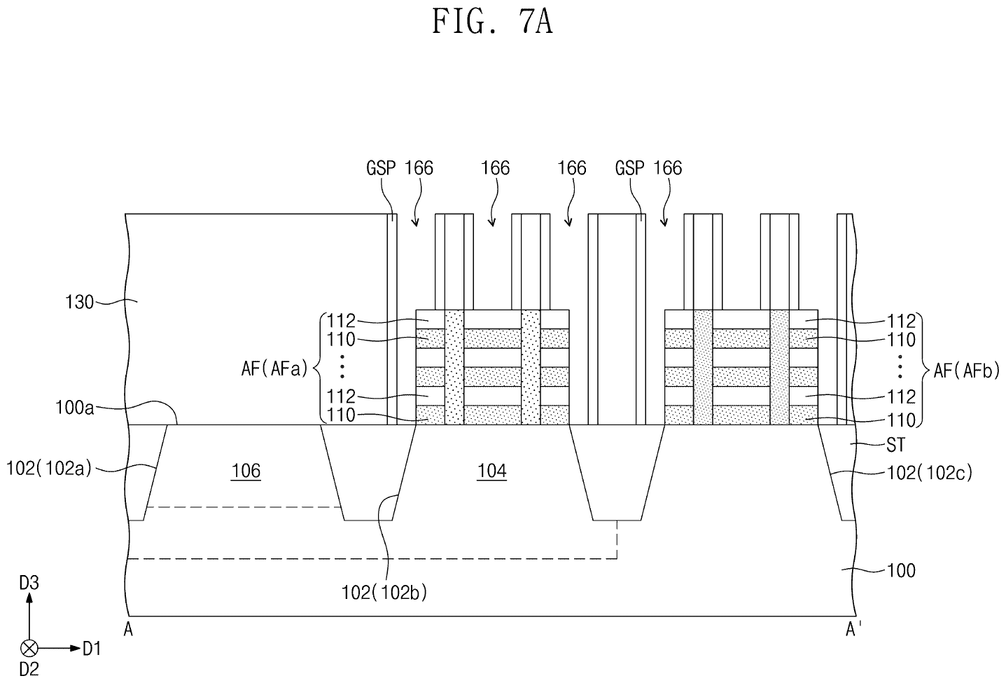

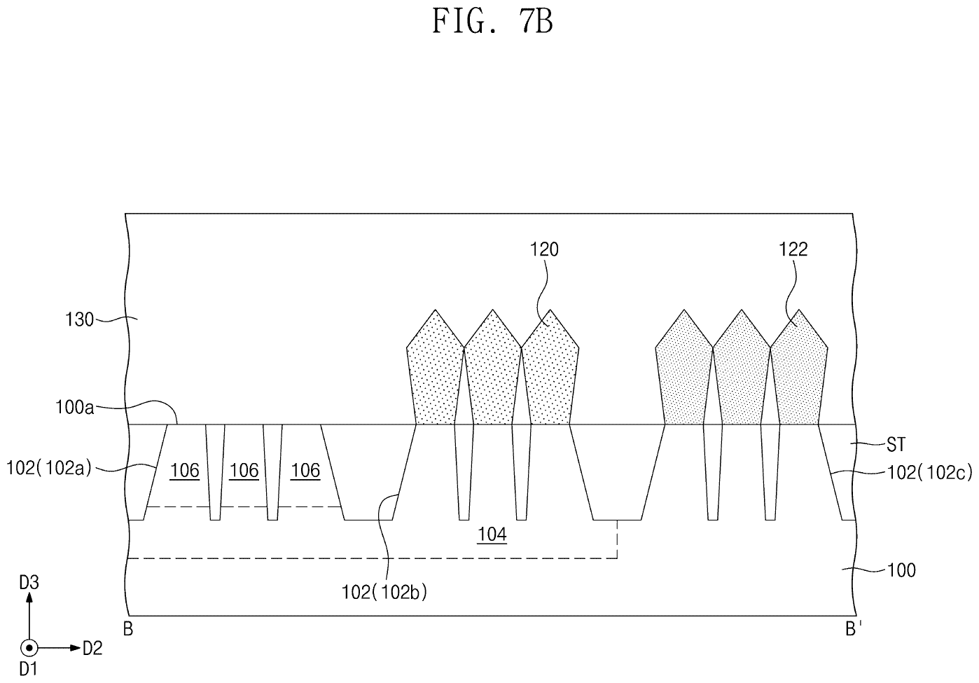

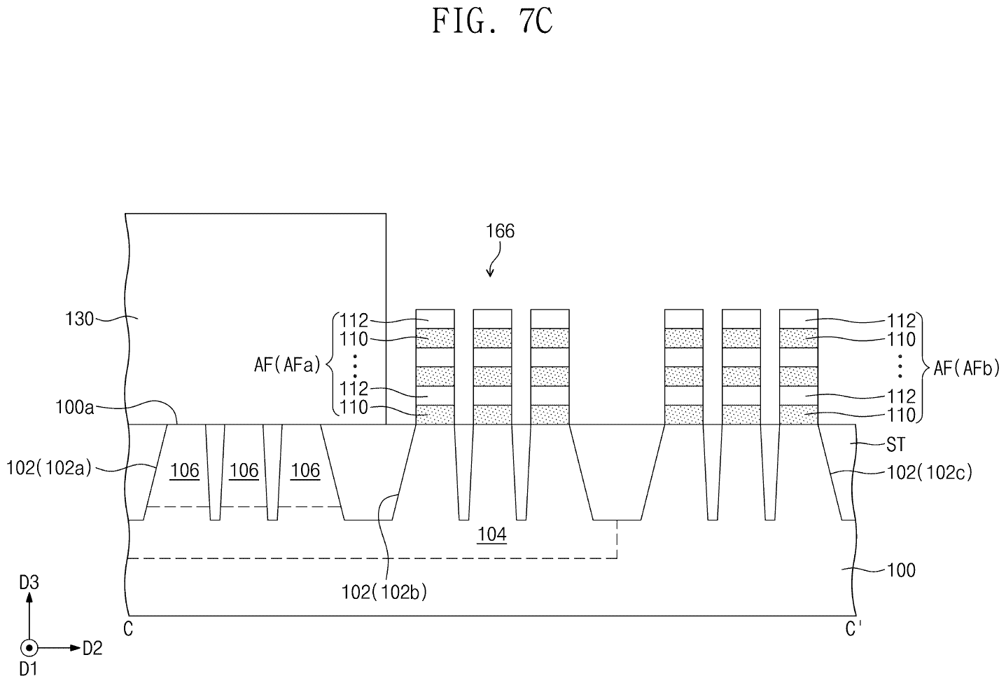

Referring to FIGS. 1, 7A, 7B, and 7C, the lower insulating layer 130 may be planarized to expose the sacrificial gate pattern 160. The gate mask pattern 164 may be removed by a planarization process. The sacrificial gate pattern 160 and the etch stop pattern 162 may be removed, and as a result, gap regions 166 may be formed in the lower insulating layer 130. Each of the gap regions 166 may be formed to expose corresponding ones of the active fins AF. The formation of the gap regions 166 may include performing an etching process, which has an etch selectivity with respect to the gate spacers GSP, the lower insulating layer 130, and the etch stop pattern 162, to selectively remove the sacrificial gate pattern 160 and removing the etch stop pattern 162 to expose the semiconductor and sacrificial patterns 112 and 110 of the corresponding active fins AF.

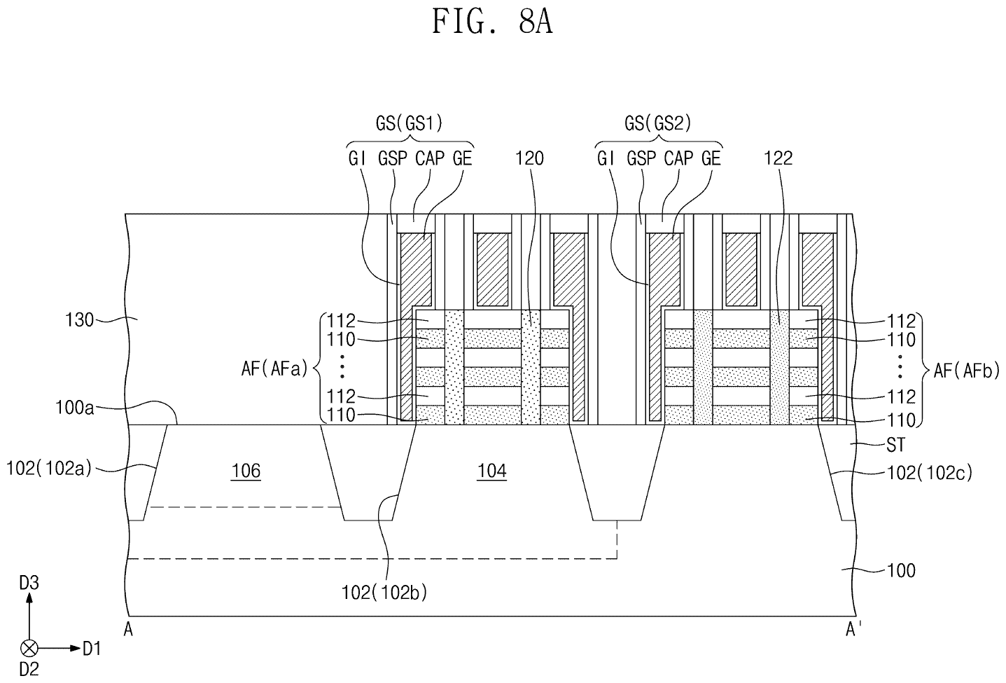

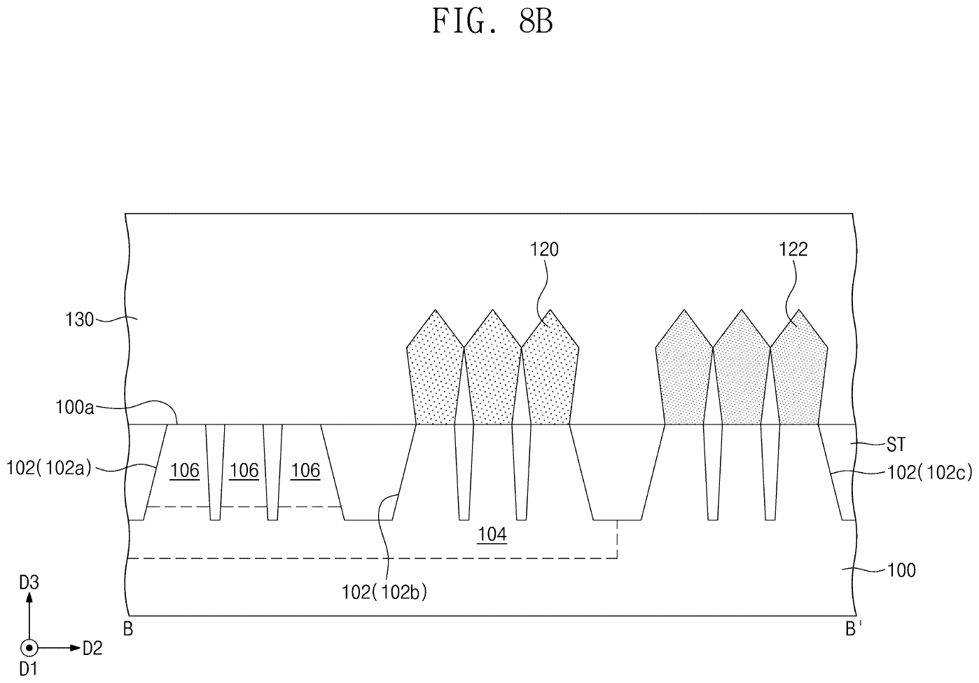

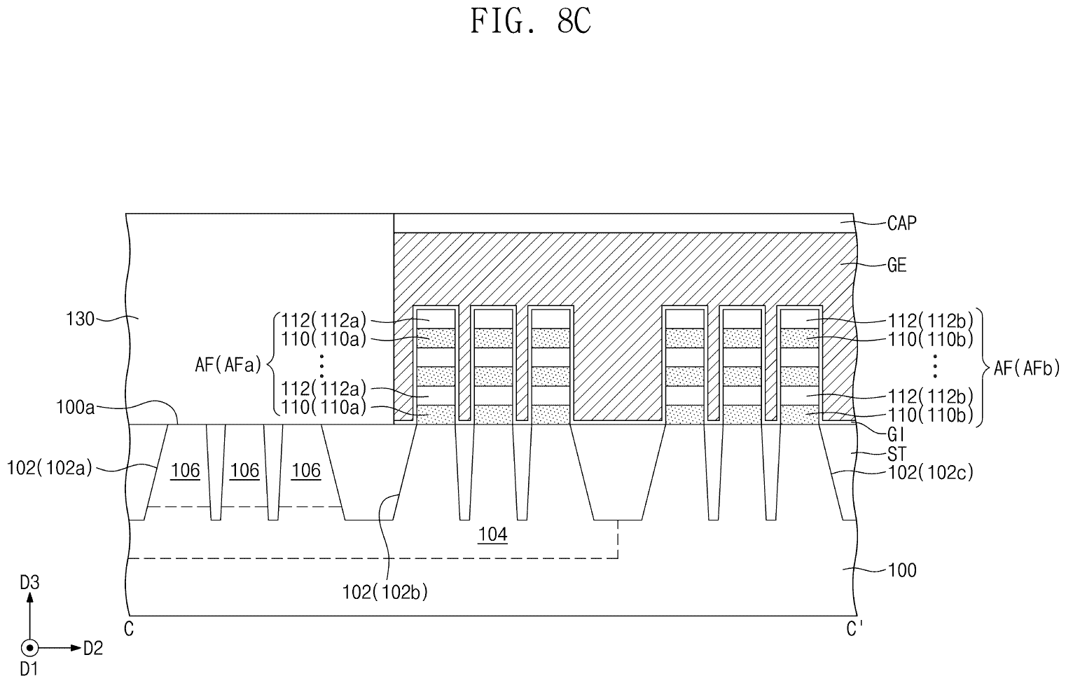

Referring to FIGS. 1, 8A, 8B, and 8C, the gate insulating pattern GI and the gate electrode GE may be formed to fill each of the gap regions 166. The formation of the gate insulating pattern GI and the gate electrode GE may include forming a gate insulating layer to conformally cover an inner surface of each of the gap regions 166, forming a gate conductive layer to fill a remaining portion of each of the gap regions 166, and performing a planarization process to expose the lower insulating layer 130 and to locally form the gate insulating pattern GI and the gate electrode GE in each of the gap regions 166. Upper portions of the gate insulating pattern GI and the gate electrode GE may be recessed to form a groove region between the gate spacers GSP. The gate capping pattern CAP may be formed in the groove region. The formation of the gate capping pattern CAP may include forming a gate capping layer on the lower insulating layer 130 to fill the groove region and planarizing the gate capping layer to expose the lower insulating layer 130.

Referring back to FIGS. 1, 2A, 2B, and 2C, the upper insulating layer 140 may be formed on the lower insulating layer 130. The contact plugs CT may be formed in the upper and lower insulating layers 140 and 130. Each of the contact plugs CT may include the conductive pattern 150, which is provided to penetrate the upper insulating layer 140 and is extended into the lower insulating layer 130, and the barrier pattern 152, which is provided to cover the side and bottom surfaces of the conductive pattern 150. In an embodiment, the formation of the contact plugs CT may include forming contact holes in the upper and lower insulating layers 140 and 130, forming a barrier layer to fill a portion of each of the contact holes, forming a conductive layer to fill a remaining portion of each of the contact holes, and planarizing the conductive layer and the barrier layer to expose the upper insulating layer 140. As a result of the planarization process, the conductive pattern 150 and the barrier pattern 152 may be locally formed in each of the contact holes. The first contact plug CT1 and the second contact plug CT2 may be formed to be connected to the first connection pattern 120 and the second connection pattern 122, respectively.

The penetration contact plugs TCT may be formed in the upper and lower insulating layers 140 and 130. Each of the penetration contact plugs TCT may include the conductive pattern 150, which is provided to penetrate the upper and lower insulating layers 140 and 130, and the barrier pattern 152, which is provided to cover the side and bottom surfaces of the conductive pattern 150. The penetration contact plugs TCT may be formed by substantially the same process as that for the formation of the contact plugs CT. The penetration contact plugs TCT may be provided to penetrate the upper and lower insulating layers 140 and 130 and may be in direct contact with the impurity injection region 106.

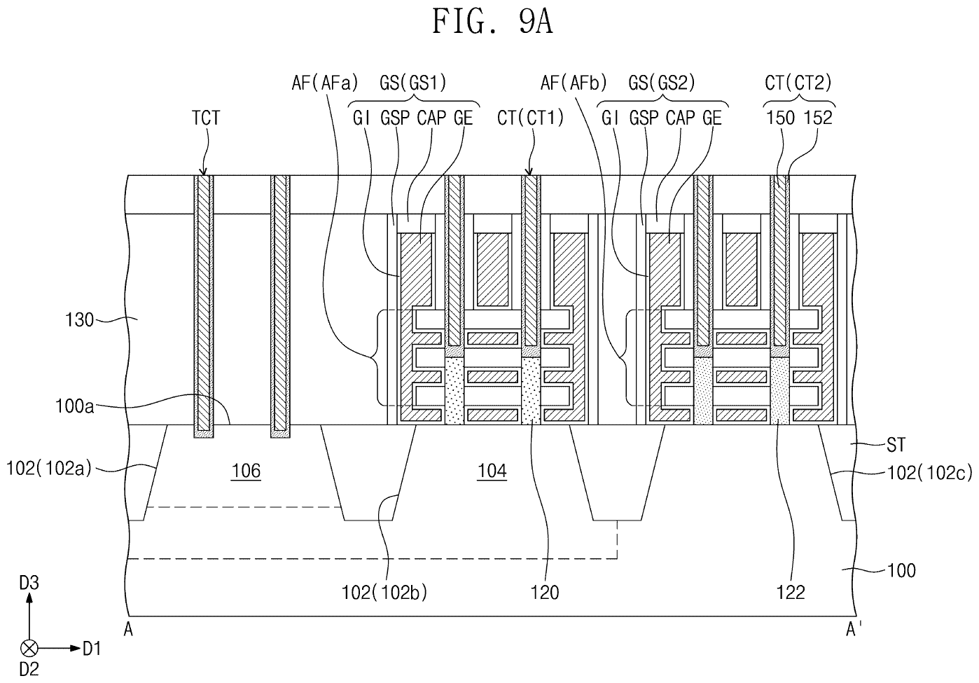

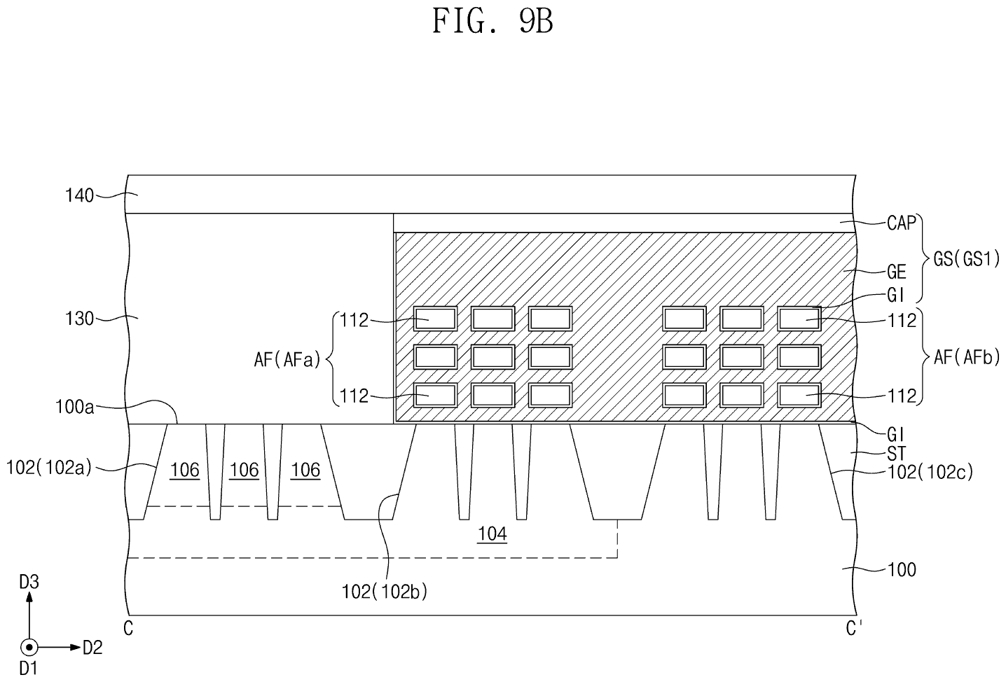

FIGS. 9A and 9B are sectional views, which are respectively taken along the lines A-A′ and C-C′ of FIG. 1 to illustrate a semiconductor device according to an embodiment of the inventive concept. For the sake of brevity, features, which are different from those of the semiconductor device described with reference to FIGS. 1, 2A, 2B, and 2C, will be mainly described below.

Referring to FIGS. 1, 2B, 9A, and 9C, the active fins AF may be disposed on the active patterns 102. The active fins AF may include the first active fin AFa on the second active pattern 102b and the second active fin AFb on the third active patterns 102c. Each of the first and second active fins AFa and AFb may include the semiconductor patterns 112, which are spaced apart from each other in the third direction D3.

The first connection pattern 120 may penetrate the semiconductor patterns 112 of the first active fin AFa and may be connected to the well region 104. The first connection pattern 120 may contain impurities of the second conductivity type. The second connection pattern 122 may penetrate the semiconductor patterns 112 of the second active fin AFb and may be connected to the substrate 100. The second connection pattern 122 may contain impurities of the first conductivity type.

The gate structures GS may be disposed on the substrate 100 to cross the active fins AF. The gate structures GS may include the first gate structures GS1 and the second gate structures GS2.

In an embodiment, the gate electrode GE and the gate insulating pattern GI of each of the gate structures GS may be extended into regions between the semiconductor patterns 112 of the corresponding active fins AF and between the corresponding active fins AF and the active patterns 102. The semiconductor patterns 112 of the active fin AF may be spaced apart from the gate electrode GE with the gate insulating pattern GI interposed therebetween. In an embodiment, the gate insulating pattern GI of each of the first gate structures GS1 may be extended into a region between the first connection pattern 120 and the gate electrode GE and may be in contact with the first connection pattern 120. The gate insulating pattern GI of each of the second gate structures GS2 may be extended into a region between the second connection pattern 122 and the gate electrode GE and may be in contact with the second connection pattern 122.

In the present embodiment, the semiconductor device may have a structure that is similar to a multi-bridge channel field effect transistor. Thus, the vertical bipolar junction transistor in the semiconductor device may have a compatible structure with the multi-bridge channel field effect transistors.

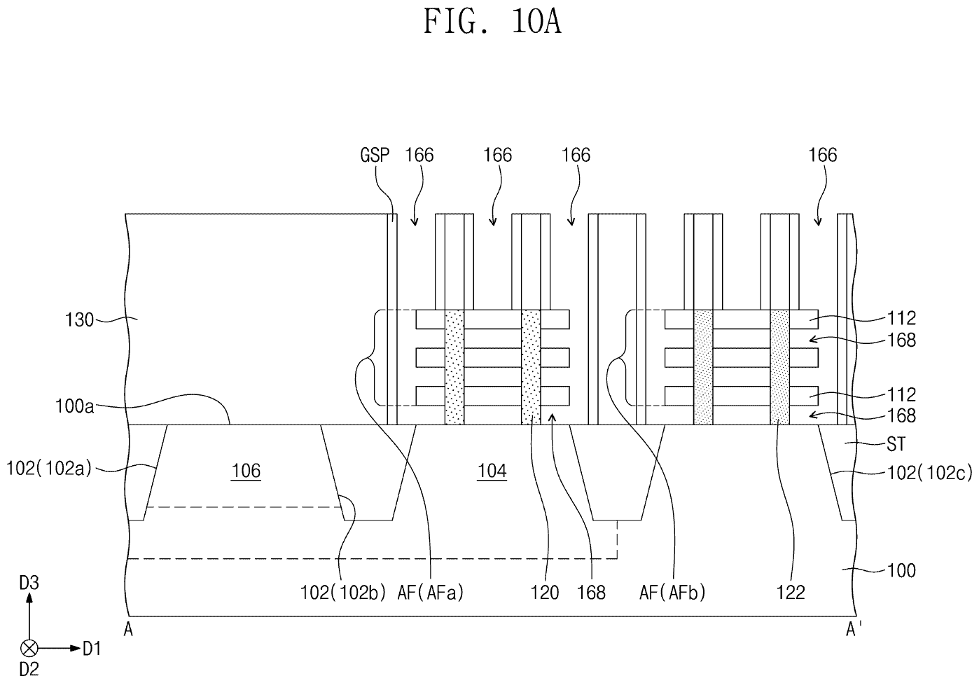

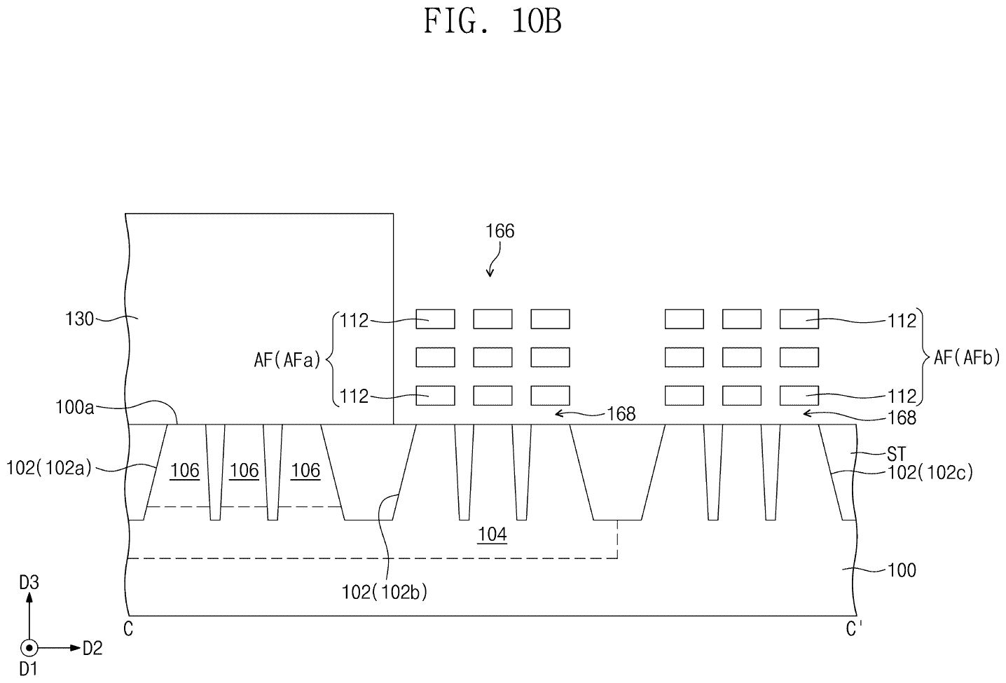

FIGS. 10A and 10B are sectional views, which are respectively taken along the lines A-A′ and C-C′ of FIG. 1 to illustrate a method of fabricating a semiconductor device according to an embodiment of the inventive concept. For the sake of brevity, features, which are different from the fabrication method described with reference to FIGS. 3A to 8A and 3B to 8B, will be mainly described below.

Referring to FIGS. 1, 7B, 10A, and 10B, the sacrificial patterns 110, which are exposed by the gap regions 166, may be selectively removed, after the formation of the gap regions 166. Since the sacrificial patterns 110 are selectively removed, empty regions 168 may be formed between the semiconductor patterns 112, and between the lowermost one of the semiconductor patterns 112 and a corresponding one of the active patterns 102. In an embodiment, the empty regions 168 may be connected to the gap regions 166 to form a single void space. Thereafter, the gate insulating pattern GI and the gate electrode GE may be formed to fill the gap regions 166 and the empty regions 168, as described with reference to FIGS. 1, 8A, 8B, and 8C.

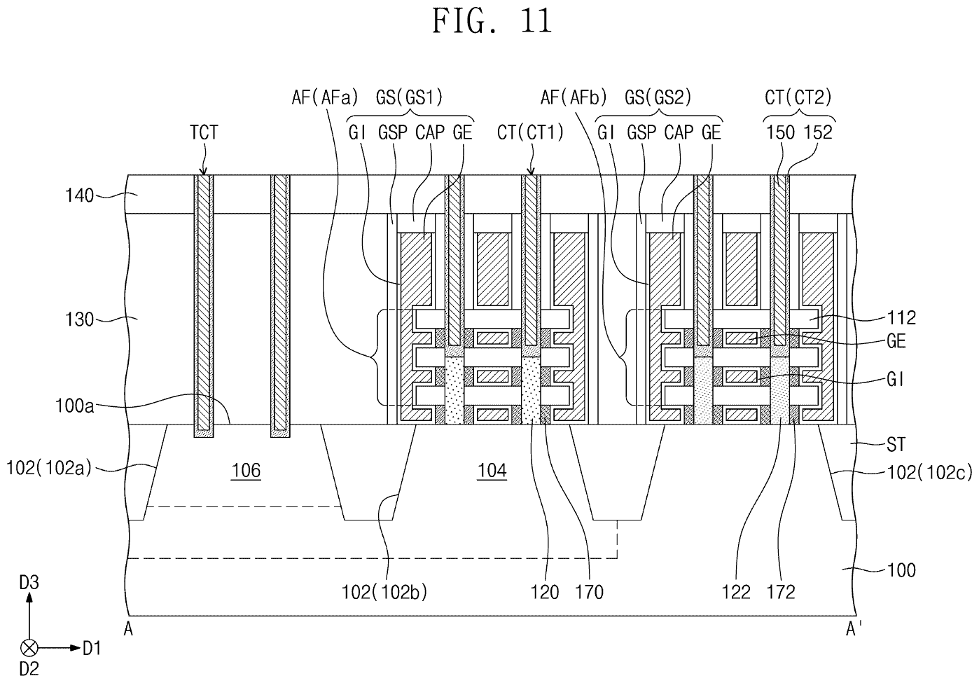

FIG. 11 is a sectional view, which is taken along the line A-A′ of FIG. 1 to illustrate a semiconductor device according to an embodiment of the inventive concept. For concise description, a previously described element may be identified by the same reference number without repeating an overlapping description thereof.

Referring to FIGS. 1, 2B, 2C, and 11, first spacer patterns 170 may be disposed between the semiconductor patterns 112 of the first active fin AFa. The first spacer patterns 170 and the semiconductor patterns 112 may be alternately stacked in the third direction D3. Each of the first spacer patterns 170 may be disposed between the semiconductor patterns 112, which are adjacent to each other in the third direction D3, or between the lowermost one of the semiconductor patterns 112 and the second active pattern 102b. The gate electrode GE of each of the first gate structures GS1 may be spaced apart from the first connection pattern 120, with the first spacer patterns 170 interposed therebetween. The gate insulating pattern GI of each of the first gate structures GS1 may be extended into a region between a corresponding one of the first spacer patterns 170 and the gate electrode GE.

Second spacer patterns 172 may be disposed between the semiconductor patterns 112 of the second active fin AFb. The second spacer patterns 172 and the semiconductor patterns 112 may be alternately stacked in the third direction D3. Each of the second spacer patterns 172 may be disposed between the semiconductor patterns 112, which are adjacent to each other in the third direction D3, or between the lowermost one of the semiconductor patterns 112 and the third active pattern 102c. The gate electrode GE of each of the second gate structures GS2 may be spaced apart from the second connection pattern 122, with the second spacer patterns 172 interposed therebetween. The gate insulating pattern GI of each of the second gate structures GS2 may be extended into a region between a corresponding one of the second spacer patterns 172 and the gate electrode GE. Except for the features described above, the semiconductor device according to the present embodiment may be configured to have substantially the same features as those of the semiconductor device described with reference to FIGS. 1, 2B, 9A, and 9C.

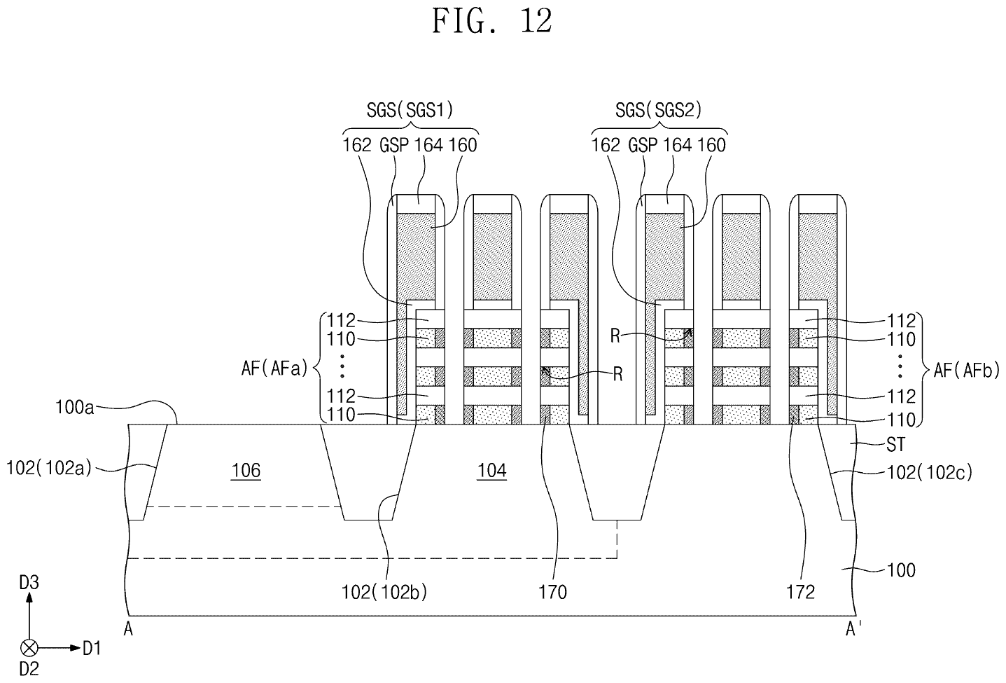

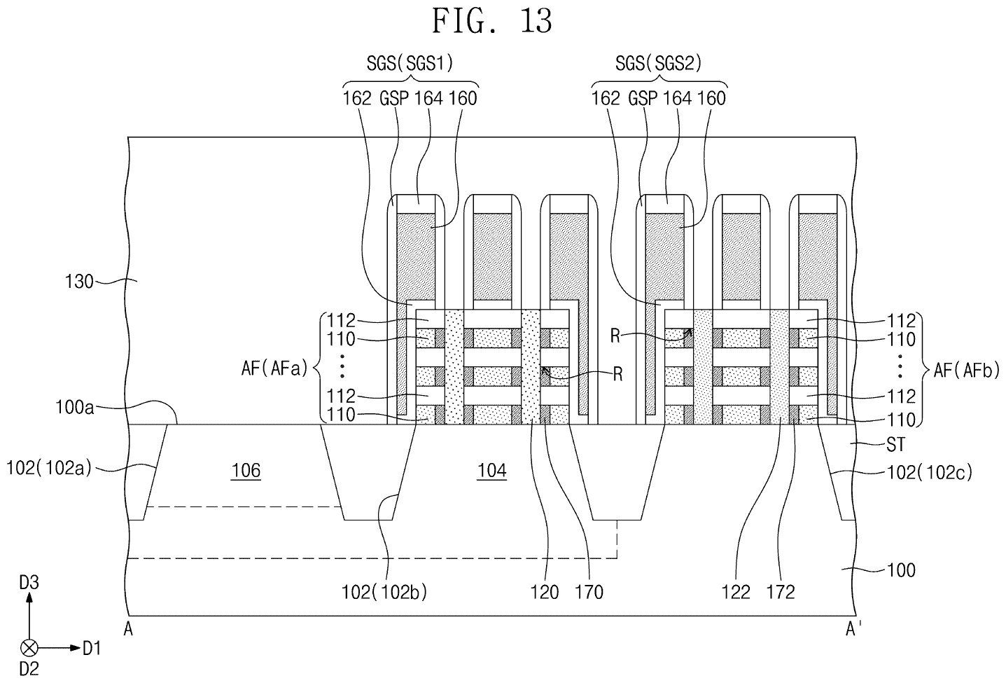

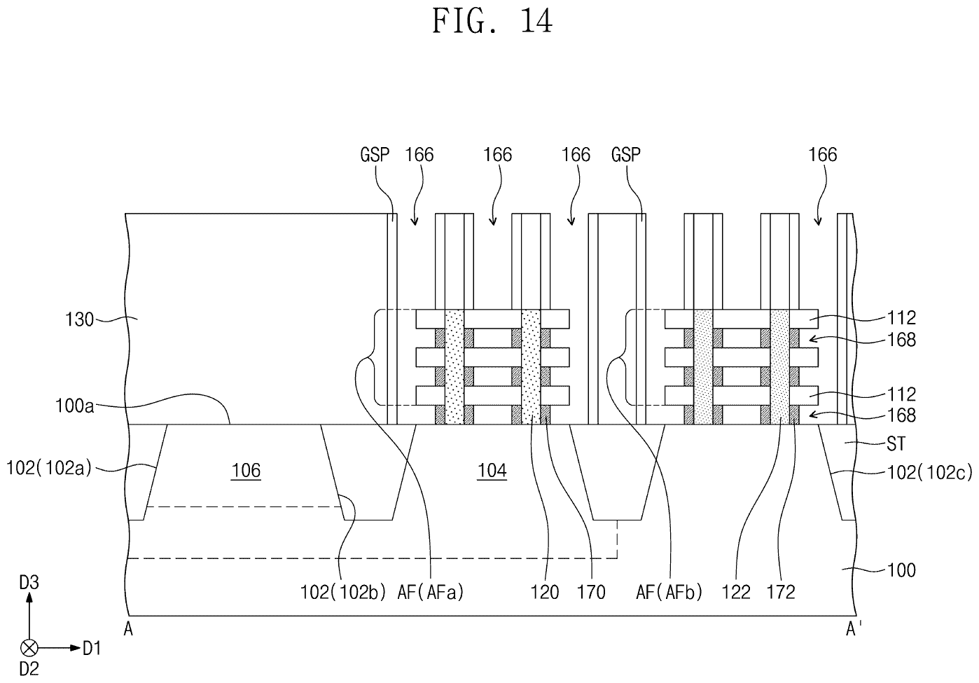

FIGS. 12 to 14 are sectional views, which are taken along the line A-A′ of FIG. 1 to illustrate a method of fabricating a semiconductor device according to an embodiment of the inventive concept. For the sake of brevity, features, which are different from the fabrication method described with reference to FIGS. 3A to 8C, will be mainly described below.

Referring to FIGS. 1, 5B, 5C, and 12, a portion of the correspond active fin AF between the first sacrificial gate structures SGS1 may be removed. In an embodiment, a portion of the first active fin AFa between the first sacrificial gate structures SGS1 may be removed. Thus, the side surfaces of the sacrificial and semiconductor patterns 110 and 112 of the first active fin AFa and the top surface of the second active pattern 102b may be exposed between the first sacrificial gate structures SGS1. In addition, a portion of the correspond active fin AF between the second sacrificial gate structures SGS2 may be removed. In an embodiment, a portion of the second active fin AFb between the second sacrificial gate structures SGS2 may be removed. Thus, the side surfaces of the sacrificial and semiconductor patterns 110 and 112 of the second active fin AFb and the top surface of the third active pattern 102c may be exposed between the second sacrificial gate structures SGS2.

The exposed side surfaces of the sacrificial patterns 110 may be horizontally recessed to form recess regions R. The recess regions R may be formed by performing a wet etching process of selectively etching the sacrificial patterns 110. Thereafter, the first and second spacer patterns 170 and 172 may be formed in the recess regions R, respectively. The formation of the first and second spacer patterns 170 and 172 may include conformally forming a spacer layer on the substrate 100 to fill the recess regions R and anisotropically etching the spacer layer to locally form the first and second spacer patterns 170 and 172 in the recess regions R, respectively. The first and second spacer patterns 170 and 172 may be formed of or include at least one of low-k dielectric materials.

Referring to FIGS. 1, 6B, 6C, and 13, the first connection pattern 120 may be formed on the second active pattern 102b between the first sacrificial gate structures SGS1. The first connection pattern 120 may be in contact with side surfaces of the semiconductor patterns 112 of the first active fin AFa and may be spaced apart from the sacrificial patterns 110 of the first active fin AFa. Each of the first spacer patterns 170 may be interposed between each of the sacrificial patterns 110 of the first active fin AFa and the first connection pattern 120. The second connection pattern 122 may be formed on the third active pattern 102c between the second sacrificial gate structures SGS2. The second connection pattern 122 may be in contact with side surfaces of the semiconductor patterns 112 of the second active fin AFb and may be spaced apart from the sacrificial patterns 110 of the second active fin AFb. Each of the second spacer patterns 172 may be interposed between each of the sacrificial patterns 110 of the second active fin AFb and the second connection pattern 122. The lower insulating layer 130 may be formed on the substrate 100 to cover the active fins AF, the first and second connection patterns 120 and 122, and the sacrificial gate structures SGS.

Referring to FIGS. 1, 7B, 7C, and 14, the gap regions 166 may be formed in the lower insulating layer 130. The sacrificial patterns 110, which are exposed by the gap regions 166, may be selectively removed, after the formation of the gap regions 166. Since the sacrificial patterns 110 are selectively removed, the empty regions 168 may be formed between the semiconductor patterns 112, and between the lowermost one of the semiconductor patterns 112 and a corresponding one of the active patterns 102. In an embodiment, the empty regions 168 may be connected to the gap regions 166 to form a single void space. Each of the empty regions 168 may be formed to expose a corresponding one of the first and second spacer patterns 170 and 172. Thereafter, the gate insulating pattern GI and the gate electrode GE may be formed to fill the gap regions 166 and the empty regions 168, as described with reference to FIGS. 1, 8A, 8B, and 8C.

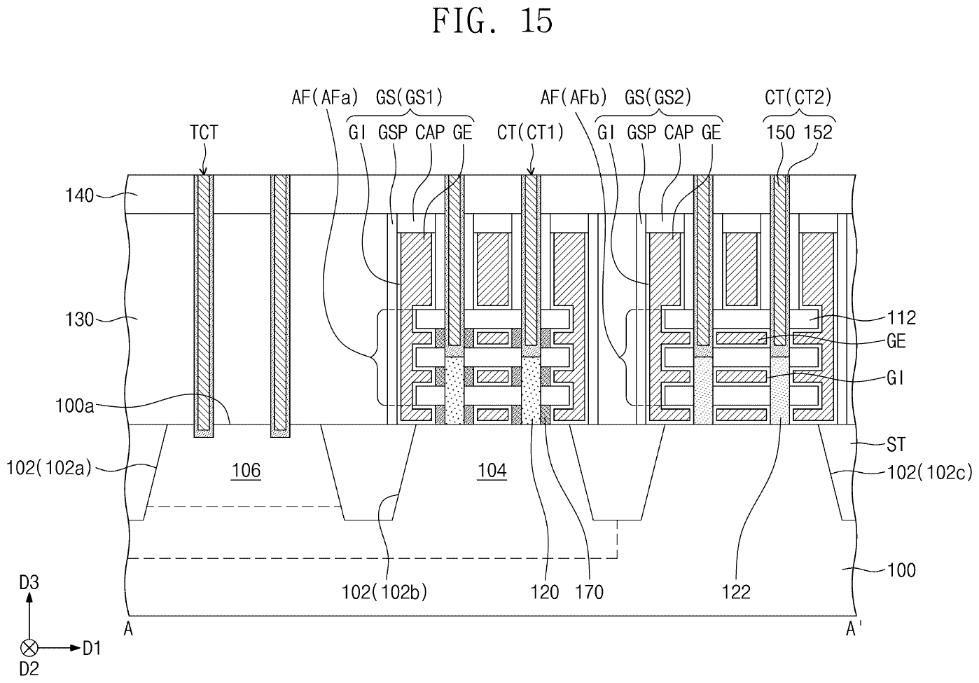

FIG. 15 is a sectional view, which is taken along the line A-A′ of FIG. 1 to illustrate a semiconductor device according to an embodiment of the inventive concept. Referring to FIGS. 1, 2B, 2C, and 15, the second spacer patterns 172 may be omitted, and except for this difference, the semiconductor device according to the present embodiment may be configured to have substantially the same features as those of the semiconductor device described with reference to FIGS. 1, 2B, 2C, and 11.

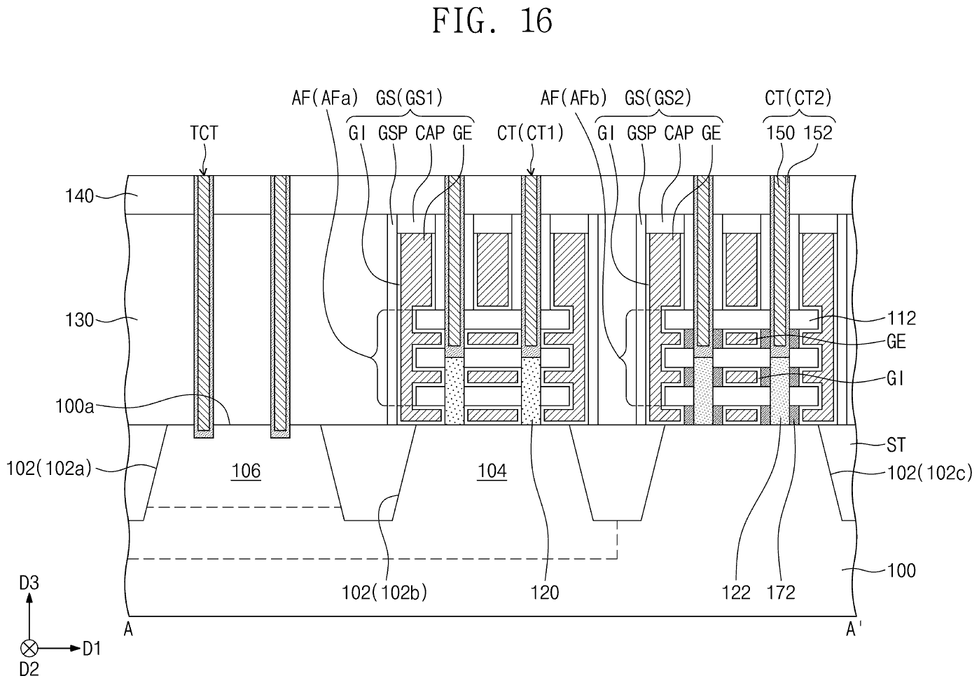

FIG. 16 is a sectional view, which is taken along the line A-A′ of FIG. 1 to illustrate a semiconductor device according to an embodiment of the inventive concept. Referring to FIGS. 1, 2B, 2C, and 16, the first spacer patterns 170 may be omitted, and except for this difference, the semiconductor device according to the present embodiment may be configured to have substantially the same features as those of the semiconductor device described with reference to FIGS. 1, 2B, 2C, and 11.

According to an embodiment of the inventive concept, the active fins may be removed from the impurity injection region 106, and an ion implantation process may be performed on the resulting structure. Thus, it may be possible to form a PN junction in a lower portion of the first active pattern 102a. Since a density of state is lower in the lower portion of the first active pattern 102a than in the upper portion, it may be possible to improve the uniformity of voltage values more effectively. In addition, since a PNP junction of a vertical bipolar junction transistor is formed adjacent to a lower portion of the device isolation pattern ST, a leakage current issue may be reduced.

Furthermore, the penetration contact plug TCT may be in direct contact with or connected to the impurity injection region 106, and this may make it possible to reduce an electric resistance between the impurity injection region 106 and the penetration contact plug TCT. Accordingly, the electric characteristics of the semiconductor device may be improved.

The above-described semiconductor device according to embodiments of the inventive concepts may be included in various electronic products including display devices, televisions, computers (e.g., laptops), phones (e.g., smartphones), severs, infotainment systems, or the like.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a well region disposed in a substrate;
an impurity injection region disposed in the well region;
an active fin on the well region;
a lower insulating layer covering the impurity injection region and the active fin; and
a connection pattern provided to penetrate the active fin and connected to the well region,
wherein the substrate and the impurity injection region have a first conductivity type,
the well region has a second conductivity type different from the first conductivity type, and
an uppermost portion of the impurity injection region is in direct contact with the lower insulating layer.

2. The semiconductor device of claim 1, wherein the connection pattern comprises impurities of the second conductivity type.

3. The semiconductor device of claim 1, further comprising:
a contact plug connected to the connection pattern; and
gate structures crossing the active fin,
wherein the contact plug is disposed between the gate structures.

4. The semiconductor device of claim 3, wherein each of the gate structures comprises:
a gate electrode crossing the active fin; and
gate spacers on side surfaces of the gate electrode,
wherein side surfaces of the contact plug are in contact with the gate spacers.

5. The semiconductor device of claim 1, wherein the active fin comprises semiconductor patterns, which are spaced apart from each other in a vertical direction perpendicular to a top surface of the substrate, and
the connection pattern is provided to penetrate the semiconductor patterns and is connected to the well region.

6. The semiconductor device of claim 5, wherein the active fin further comprises sacrificial patterns interposed between the semiconductor patterns, and
the connection pattern is provided to also penetrate the sacrificial patterns.

7. The semiconductor device of claim 5, further comprising a gate electrode, which is disposed on the active fin to cross the active fin,
wherein the gate electrode is extended into a space between the semiconductor patterns.

8. The semiconductor device of claim 7, further comprising spacer patterns interposed between the semiconductor patterns,
wherein the gate electrode is spaced apart from the connection pattern, with the spacer patterns interposed therebetween.

9. The semiconductor device of claim 1, further comprising a penetration contact plug connected to the impurity injection region,
wherein the penetration contact plug is provided to penetrate the lower insulating layer and is in direct contact with the impurity injection region.

10. The semiconductor device of claim 1, further comprising:
a first contact plug connected to the connection pattern; and
gate structures disposed on the active fin,
wherein the first contact plug is disposed between the gate structures, and
the lower insulating layer covers the first contact plug and the gate structures.

11. A semiconductor device, comprising:
a well region disposed in a substrate;
an impurity injection region disposed in the well region;
a first active fin disposed on the well region, the first active fin comprising first semiconductor patterns, which are spaced apart from each other in a vertical direction perpendicular to a top surface of the substrate;
a second active fin disposed on the substrate, the second active fin comprising second semiconductor patterns, which are spaced apart from each other in the vertical direction;
a first connection pattern provided to penetrate the first active fin and connected to the well region;
a second connection pattern provided to penetrate the second active fin and connected to the substrate; and
a lower insulating layer covering the first and second active fins,
wherein the substrate and the impurity injection region have a first conductivity type,
the well region has a second conductivity type different from the first conductivity type, and
an uppermost portion of the impurity injection region is in direct contact with the lower insulating layer.

12. The semiconductor device of claim 11, wherein the first connection pattern comprises impurities of the second conductivity type, and
the second connection pattern comprises impurities of the first conductivity type.

13. The semiconductor device of claim 11, further comprising a penetration contact plug connected to the impurity injection region,
wherein the penetration contact plug is provided to penetrate the lower insulating layer and is in direct contact with the impurity injection region.

14. The semiconductor device of claim 11, further comprising:
a first contact plug connected to the first connection pattern; and
first gate structures disposed on the first active fin,
wherein the first contact plug is disposed between the first gate structures, and
the lower insulating layer covers the first contact plug and the first gate structures.

15. The semiconductor device of claim 14, further comprising:
a second contact plug connected to the second connection pattern; and
second gate structures disposed on the second active fin,
wherein the second contact plug is disposed between the second gate structures, and
the lower insulating layer covers the second contact plug and the second gate structures.

16. The semiconductor device of claim 15, wherein each of the first and second gate structures comprises:
a gate electrode; and
gate spacers on opposite side surfaces of the gate electrode,
wherein the first contact plug is in contact with the gate spacers of the first gate structure, and
the second contact plug is in contact with the gate spacers of the second gate structure.

17. A semiconductor device, comprising:
device isolation patterns disposed in a substrate;
a first active pattern, a second active pattern, and a third active pattern, which are spaced apart from each other with the device isolation patterns interposed therebetween;
a first active fin on the second active pattern; and
a lower insulating layer covering the first active fin,
wherein the first active pattern comprises an impurity injection region of a first conductivity type,
the second active pattern comprises a well region of a second conductivity type different from the first conductivity type,
the third active pattern has the first conductivity type, and
the lower insulating layer is in direct contact with a top surface of the first active pattern.

18. The semiconductor device of claim 17, wherein the well region is extended to a lower portion of the first active pattern along a bottom surface of corresponding device isolation patterns of the device isolation patterns, and
the impurity injection region and the well region form a PN junction in the lower portion of the first active pattern.

19. The semiconductor device of claim 17, further comprising a penetration contact plug connected to the first active pattern,
wherein the penetration contact plug is provided to penetrate the lower insulating layer and is in direct contact with the first active pattern.

20. The semiconductor device of claim 17, further comprising:
a second active fin on the third active pattern;
a first connection pattern provided to penetrate the first active fin and connected to the second active pattern; and
a second connection pattern provided to penetrate the second active fin and connected to the third active pattern,
wherein the first connection pattern comprises impurities of the first conductivity type, and
the second connection pattern comprises impurities of the second conductivity type.
